(19) United States
(12) Patent Application Publication
(10) Pub. No.: US 2014/0124785 A1
(43) Pub. Date: May 8, 2014

(54) SEMICONDUCTOR DEVICE AND METHOD FOR MANUFACTURING SAME

(71) Applicant: Kenshi Tada, Osaka-shi (JP)

(72) Inventor: Kenshi Tada, Osaka-shi (JP)

(73) Assignee: Sharp Kabushiki Kaisha, Osaka-shi, Osaka (JP)

(21) Appl. No.: 14/125,322

(22) PCT Filed: Jun. 11, 2012
(86) PCT No.: PCT/JP2012/064901

§ 371 Date: Dec. 11, 2013

(30) Foreign Application Priority Data
Jun. 15, 2011 (JP) 2011-133072

(51) Int. Cl. H01L 27/12

(52) U.S. Cl. CPC H01L 27/1296; H01L 27/124
USPC 257/59; 438/34; 257/72

(57) ABSTRACT

This semiconductor device fabricating method includes the steps of: (A) providing a supporting structure (10) in which a first separating layer (3) and a first insulating layer (5) have been stacked in this order on the surface of a supporting base (1); (B) providing a sustaining structure (30); (C) forming a thin-film transistor (M1, M2) on the first insulating layer (5); (D) forming a second insulating layer (20) that covers the thin-film transistor (M1, M2); (E) joining the supporting structure on which the second insulating layer has been formed onto the sustaining structure (30) so that the thin-film transistor (M1, M2) faces the sustaining structure (30) with the second insulating layer (20) interposed, thereby obtaining a joined structure (40); (F) removing the supporting base and at least a part of the first separating layer (3) from the joined structure (40); and (G) forming a pixel electrode (33) on the other side of the joined structure (40), from which the supporting base has already been removed, opposite from the sustaining structure (30) so that the pixel electrode (33) is electrically connected to the thin-film transistor (M1, M2).

### TECHNICAL FIELD

The present invention relates to a semiconductor device and a method for fabricating the device.

### BACKGROUND ART

An active-matrix-addressed display device uses an active-matrix substrate in which a large number of thin-film transistors (TFTs) are arranged in matrix on a substrate such as a glass substrate (and which is also called a “TFT substrate”). Those TFTs are formed on the substrate by the same manufacturing technologies as the ones to fabricate a semiconductor integrated circuit including a deposition process such as a CVD process and a photolithographic process. The fabrication of TFTs involves a high-temperature process. That is why a substrate with good heat resistance such as a highly heat resistant glass substrate is usually used as the substrate.

However, such a highly heat resistant glass substrate is so heavy and is deformable so easily that such a substrate should not be used according to the intended use of the product. For example, a flexible display which is thin, lightweight, hardly breakable, and deformable into a curved shape has attracted a lot of attention recently. But such a flexible display uses a TFT substrate in which TFTs have been formed on a flexible substrate such as a resin substrate (and which will be referred to herein as a “flexible TFT substrate”).

If a flexible TFT substrate is going to be fabricated by forming TFTs directly on a resin substrate, then the process temperature needs to fall within a narrower range compared to a situation where those TFTs are fabricated on a conventional heat resistant glass substrate. For example, when TFTs are to be formed on a heat resistant glass substrate, the process temperature may be about 600° C. or less. On the other hand, when TFTs are to be formed on a resin substrate, the process temperature should be decreased to about 200° C. or less. The reason is that if the process temperature exceeded 200° C., the resin substrate could be deformed or softened. Optionally, the process temperature can be raised if a polyimide resin substrate, for example, is used as a resin substrate with heat resistance. However, the polyimide resin substrate generally has an inferior optical transmissivity, and therefore, is not suitable for a flexible display. On top of that, it is difficult to perform a fine-line patterning process on a resin substrate, which is also a problem. For these reasons, it is difficult to realize a high-definition display using such a substrate.

Thus, in order to overcome these problems, a method for fabricating a flexible TFT substrate by forming TFTs on a supporting base with good heat resistance and then transferring those TFTs completed onto a resin substrate has been proposed. For example, according to the method disclosed in Patent Document No. 1, after TFTs and pixel electrodes have been formed on a supporting base such as a glass substrate, an arbitrary substrate is mounted on them as a sustaining structure. After that, those TFTs are transferred onto the resin substrate by separating the supporting base from the TFTs and other members. In this manner, those TFTs which have been fabricated with high precision at a high process temperature can be transferred onto any arbitrary substrate such as a resin substrate.

FIG. 1 is a cross-sectional view of a liquid crystal display device fabricated by the method disclosed in Patent Document No. 1. The TFT substrate 2000 of this liquid crystal display device has a display area 2000A including a plurality of pixels and a non-display area (which will be referred to herein as a “peripheral area”) 2000B. In the display area 2000A, a thin-film transistor M1 is provided for each of those pixels and functions as a switching element. In the peripheral area 2000B, on the other hand, a driver circuit including thin-film transistors M2 and other circuit elements has been formed.

According to Patent Document No. 1, these thin-film transistors M1 and M2 have been formed on the TFT substrate 2000 by the transfer technique.

Specifically, first of all, on a supporting base (not shown) on which a separating layer has been formed, an insulating layer 1000, the thin-film transistors M1, M2, a protective layer 1600 and a conductive film 1700 are stacked in this order. Each of the thin-film transistors M1 and M2 is a top gate TFT and includes a semiconductor layer 1100, a gate insulating layer 1200, a gate electrode (gate line) 1300, and source and drain electrodes 1400. The conductive layer 1700 has been formed on the protective layer 1600 and is connected to the drain electrode 1400 in a contact hole which has been cut through the protective layer 1600. Also, the conductive layer 1700 is in contact with the separating layer on the supporting base (not shown) in an opening which has been cut through the protective layer 1600 and the insulating layer 1000.

Thereafter, an adhesive layer 1800 is applied to cover the thin-film transistors M1, M2 and then bonded onto a substrate (such as a resin substrate) 1900 to be a sustaining structure, thereby obtaining a joined structure. Subsequently, the supporting base is separated and removed from the joined structure by subjecting the separating layer to ablation with a laser beam, for example. In this manner, the TFT substrate 2000 is completed. After the supporting base has been removed, a portion 1702 of the conductive film 1700 is exposed on the surface. This exposed portion 1702 will function as a pixel electrode when a display device is completed. After the supporting base has been removed, the TFT substrate 2000 is bonded to a counter substrate 480, of which the surface is covered with an electrode 482, with a liquid crystal layer 460 interposed between them. In this manner, a liquid crystal display device is completed. A voltage is applied to the liquid crystal layer 460 through the portion 1702 of the conductive film 1700 and the electrode 482.

The TFTs that have been obtained by performing a TFT fabricating process using a supporting base which is suitable for forming TFTs can be transferred in this manner onto any arbitrary substrate according to the intended use of the display device.

Patent Document No. 2 discloses a method for fabricating a TFT substrate by using such a transfer technique in order to increase the degree of planarity of a pixel electrode. According to that method, an amorphous silicon layer to be a separating layer, a light reflective pixel electrode (such as a tungsten electrode), TFTs and a substrate to be a sustaining structure are stacked in this order on a transparent supporting base. Thereafter, the supporting base is separated and removed by being irradiated with a laser beam through itself, thereby obtaining a TFT substrate.

### CITATION LIST

### Patent Literature

Patent Document No. 1: Japanese Laid-Open Patent Publication No. 10-125931
Patent Document No. 2: Japanese Laid-Open Patent Publication No. 2008-191206

### SUMMARY OF INVENTION

### Technical Problem

If the method disclosed in Patent Document No. 1 is adopted, however, it is difficult to increase the aperture ratio of the display device, which is a problem.

The present inventors have found that the TFT substrate 2000 obtained by the method of Patent Document No. 1 has a planar structure such as the one shown in FIG. 2.

In the display area 2000A of the TFT substrate 2000, arranged are source lines S which run along columns of pixels, gate lines G which run along rows of pixels, and thin-film transistors M1. Each of the gate lines G is electrically connected to the gate electrode 1300 of its associated thin-film transistors M1, and each of the source lines S is electrically connected to their associated source electrodes 1400. Each of the thin-film transistors M1 is arranged in the vicinity of the intersection between its associated source line S and gate line G. Also, a (bottom) portion 1702 of the conductive film functioning as a pixel electrode is arranged inside each pixel.

In the peripheral area 2000B, on the other hand, a driver 94 has been formed by COG (chip on glass) mounting technique, and a flexible printed circuit board (FPC board) 90 has also been mounted. The driver 94 is connected through bonding pads P1 in its terminal section in order to receive a signal from an external circuit. And the input terminals of the driver are connected to external lines 92 that are arranged on the FPC board 90 via bonding pads P2. In the TFT substrate 2000 shown in FIG. 2, each portion 1702 of the transparent conductive film functioning as a pixel electrode is located only in a region where there are no thin-film transistors M1 or lines G, S. For that reason, the area of the pixel electrode cannot be increased and it is difficult to increase the aperture ratio.

In addition, holes should be cut through the relatively thick protective layer 1600, and it is difficult to cut a plurality of holes uniformly by etching, which is also a problem. On top of that, when the supporting base is separated and removed, process damage could be done on portions of the transparent conductive film in the holes, or the device might be broken down due to electrostatic discharge (ESD).

What is more, according to the method disclosed in Patent Document No. 2, pixel electrodes are formed on a peeling layer to be irradiated with a laser beam, and TFTs should be formed on the pixel electrodes. That is why the material of the pixel electrodes is also limited in terms of the degree of close contact and heat resistance. For example, it is difficult to use a light-transmitting conductive film such as ITO as a material for the pixel electrodes. That is why this method cannot be applied to a transmissive display device.

It is therefore an object of an embodiment of the present invention to overcome these problems by forming a pixel electrode with an increased area using an arbitrary conductive material and increasing the aperture ratio for a semiconductor device which is obtained by transferring thin-film transistors that have been formed on a supporting base onto another predetermined substrate.

### Solution to Problem

A semiconductor device fabricating method according to an embodiment of the present invention is a method for fabricating a semiconductor device including a thin-film transistor. The method includes the steps of: (A) providing a supporting structure in which a first separating layer and a first insulating layer have been stacked in this order on the surface of a supporting base; (B) providing a sustaining structure including a substrate; (C) forming a thin-film transistor, including a semiconductor layer, a gate insulating layer, and a gate electrode, on the first insulating layer; (D) forming a second insulating layer that covers the thin-film transistor; (E) joining the supporting structure on which the second insulating layer has been formed onto the sustaining structure so that the thin-film transistor faces the sustaining structure with the second insulating layer interposed, thereby obtaining a joined structure; (F) removing the supporting base and at least a part of the first separating layer from the joined structure; and (G) forming a pixel electrode on the other side of the joined structure, from which the supporting base has already been removed, opposite from the sustaining structure so that the pixel electrode is electrically connected to the thin-film transistor, thereby obtaining a TFT substrate.

In one preferred embodiment, the method further includes, between the steps (C) and (D), the step (H1) of forming source and drain electrodes to be electrically connected to the semiconductor layer, and the step (D) includes forming the second insulating layer on the source and drain electrodes.

The thin-film transistor may have a bottom gate structure.

In one preferred embodiment, the thin-film transistor has a top gate structure, and the method further includes, between the steps (F) and (G), the step (H2) of forming source and drain electrodes on the other side of the joined structure, from which the supporting base has already been removed, opposite from the sustaining structure so that the source and drain electrodes are electrically connected to the semiconductor layer.

In one preferred embodiment, the step (H2) includes forming the source and drain electrodes by cutting a contact hole through the first insulating layer so that the contact hole reaches a portion of the drain electrode and by depositing a conductive layer on the first insulating layer and inside the contact hole.

In one preferred embodiment, the sustaining structure includes a transparent substrate that has been stacked over the substrate with a second separating layer interposed, and the method further includes, after the step (G) has been performed, the step (I) of removing the transparent substrate and at least a part of the second separating layer from the joined structure.

In one preferred embodiment, the method further includes, after the step (G) has been performed, the step (J) of arranging a display medium layer over the pixel electrode of the TFT substrate, and the step (I) is performed after the step (J).

The substrate may be a resin substrate. And the resin substrate may be transparent.

In one preferred embodiment, the method further includes, after the step (G) has been performed, the step (J) of arranging a display medium layer over the pixel electrode of the TFT substrate, and at least a portion of the pixel electrode is located between the semiconductor layer and the display medium layer.

In one preferred embodiment, the display medium layer is a liquid crystal layer, the step (I) includes arranging the TFT substrate and a counter substrate, including a counter electrode that has been formed on its surface, with the liquid crystal layer interposed between the two substrates, and the counter substrate is a resin substrate.

A semiconductor device according to an embodiment of the present invention includes: a TFT substrate including a thin-film transistor with a bottom gate structure; a display medium layer which is arranged on the TFT substrate; and a transparent pixel electrode which is electrically connected to a drain electrode of the thin-film transistor. If a portion of the thin-film transistor including the gate electrode is called its lower portion and a portion of the thin-film transistor including the semiconductor layer is called its upper portion, the TFT substrate and the display medium layer are arranged so that the display medium layer is located under the thin-film transistor. And at least a portion of the pixel electrode is located between the gate electrode of the thin-film transistor and the display medium layer.

In one preferred embodiment, the semiconductor device further includes a line which is formed out of the same conductive film as the pixel electrode and which connects the drain and gate electrodes of the thin-film transistor together.

A semiconductor device according to another embodiment of the present invention includes: a TFT substrate including a thin-film transistor with a top gate structure; a display medium layer which is arranged on the TFT substrate; and a transparent pixel electrode which is electrically connected to the thin-film transistor. If a portion of the thin-film transistor including the gate electrode is called its upper portion and a portion of the thin-film transistor including the semiconductor layer is called its lower portion, the TFT substrate and the display medium layer are arranged so that the display medium layer is located under the thin-film transistor. And at least a portion of the pixel electrode is located between the semiconductor layer of the thin-film transistor and the display medium layer.

In one preferred embodiment, the source and drain electrodes of the thin-film transistor are arranged between the semiconductor layer and the display medium layer.

In one preferred embodiment, the display medium layer is a liquid crystal layer, the device further includes a counter substrate which is arranged to face the TFT substrate with the liquid crystal layer interposed, and the counter substrate and the TFT substrate each include a transparent resin substrate.

### Advantageous Effects of Invention

According to an embodiment of the present invention, in a process for fabricating a semiconductor device by transferring thin-film transistors that have been formed on a supporting base onto a sustaining structure including a predetermined substrate, it is not until the thin-film transistors have been transferred that pixel electrodes are formed. That is why the patterning process step to form the pixel electrodes can be performed irrespective of the wiring pattern or the locations of the thin-film transistors, and therefore, the area of the pixel electrodes can be increased. Consequently, the aperture ratio can be increased by applying this substrate to a display device.

In addition, the pixel electrodes may be made of any arbitrary material. If a transparent conductive material is used as a material for the pixel electrodes, a transmissive display device with a high aperture ratio is realized. On top of that, since the pixel electrodes can be formed on a substantially flat surface, the thickness of the display medium layer can be made substantially uniform.

Furthermore, if a flexible substrate such as a resin substrate is used as the predetermined substrate, a TFT substrate which is applicable to a flexible display is realized. In that case, if a stack of a resin substrate and a supporting base is used as the sustaining structure, the process steps of forming pixel electrodes, mounting a flexible printed circuit (FPC) board, mounting a driver by the COG technique, forming terminal portions, and bonding the TFT substrate and the counter substrate together can be performed while the TFTs are supported on the supporting base. Thus, in these process steps, the alignment accuracy can be increased with the deformation of the resin substrate decreased. Consequently, a high-definition semiconductor device is realized.

### BRIEF DESCRIPTION OF DRAWINGS

FIG. 1A cross-sectional view of the display device disclosed in Patent Document No. 1.

FIG. 2 A plan view illustrating the TFT substrate of the display device disclosed in Patent Document No. 1.

FIGS. 3 (a) through (e) are cross-sectional views illustrating respective manufacturing process steps to fabricate a TFT substrate according to a first embodiment of the present invention.

FIGS. 4 (a) through (c) are cross-sectional views illustrating respective manufacturing process steps to fabricate the TFT substrate according to the first embodiment of the present invention.

FIGS. 5 (a) through (c) are cross-sectional views illustrating respective manufacturing process steps to fabricate a counter substrate for use in the first embodiment of the present invention.

FIGS. 6 (a) and (b) are cross-sectional views illustrating respective manufacturing process steps to fabricate a display device using the TFT substrate according to the first embodiment of the present invention.

FIG. 7 A partial cross-sectional view of a display device which uses the TFT substrate according to the first embodiment of the present invention.

FIG. 8 A plan view illustrating a part of a TFT substrate according to the first embodiment of the present invention.

FIG. 9A A cross-sectional view illustrating a terminal section which has been formed on a TFT substrate according to the first embodiment of the present invention.

FIG. 9B A cross-sectional view illustrating another terminal section which has been formed on a TFT substrate according to the first embodiment of the present invention.

FIG. 9C A cross-sectional view illustrating still another terminal section which has been formed on a TFT substrate according to the first embodiment of the present invention.

FIG. 9D A cross-sectional view illustrating how to connect a source line layer, a gate line layer and a pixel electrode layer together on a TFT substrate according to the first embodiment of the present invention.

FIGS. 10 (a) through (d) are cross-sectional views illustrating respective manufacturing process steps to fabricate a TFT substrate according to a second embodiment of the present invention.

FIGS. 11 (a) through (d) are cross-sectional views illustrating respective manufacturing process steps to fabricate a TFT substrate according to the second embodiment of the present invention.

FIG. 12 A partial cross-sectional view of a display device which uses the TFT substrate according to the second embodiment of the present invention.

FIG. 13A A cross-sectional view illustrating a terminal section which has been formed on a TFT substrate according to the second embodiment of the present invention.

FIG. 13B A cross-sectional view illustrating another terminal section which has been formed on a TFT substrate according to the second embodiment of the present invention.

FIG. 13C A cross-sectional view illustrating still another terminal section which has been formed on a TFT substrate according to the second embodiment of the present invention.

FIG. 14 A cross-sectional view illustrating another TFT substrate according to the second embodiment of the present invention.

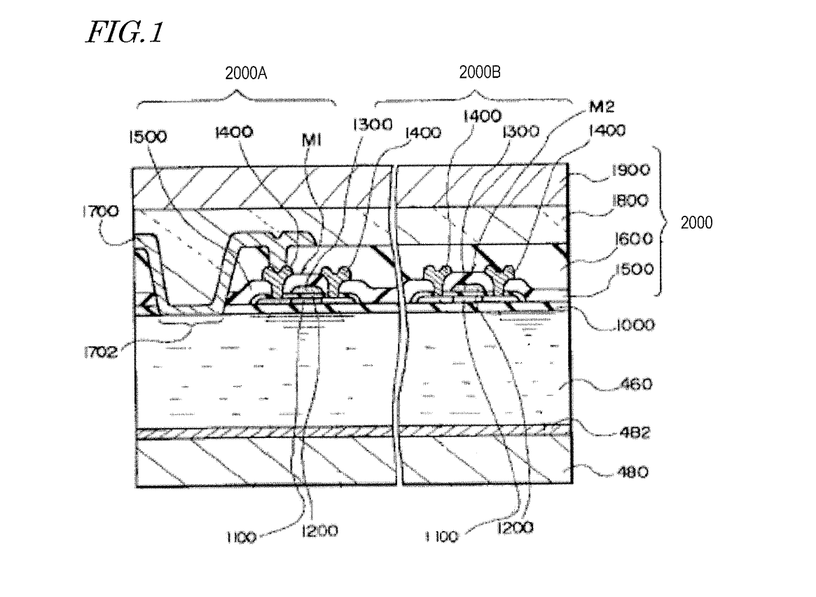

### DESCRIPTION OF EMBODIMENTS

### Embodiment 1

Hereinafter, a first embodiment of a semiconductor device according to the present invention will be described with reference to the accompanying drawings. A semiconductor device according to this first embodiment is an active-matrix substrate (TFT substrate) including TFTs with a bottom gate structure. However, a semiconductor device according to this embodiment just needs to include TFTs, and therefore, does not have to be implemented as an active-matrix substrate but may also be implemented extensively as any of various kinds of display devices such as a liquid crystal display device or an organic EL display device or any type of electronic device including such a display device.

The TFT substrate of this embodiment is obtained by transferring TFTs with a bottom gate structure, which have been formed on a supporting base, onto a predetermined substrate such as a resin substrate.

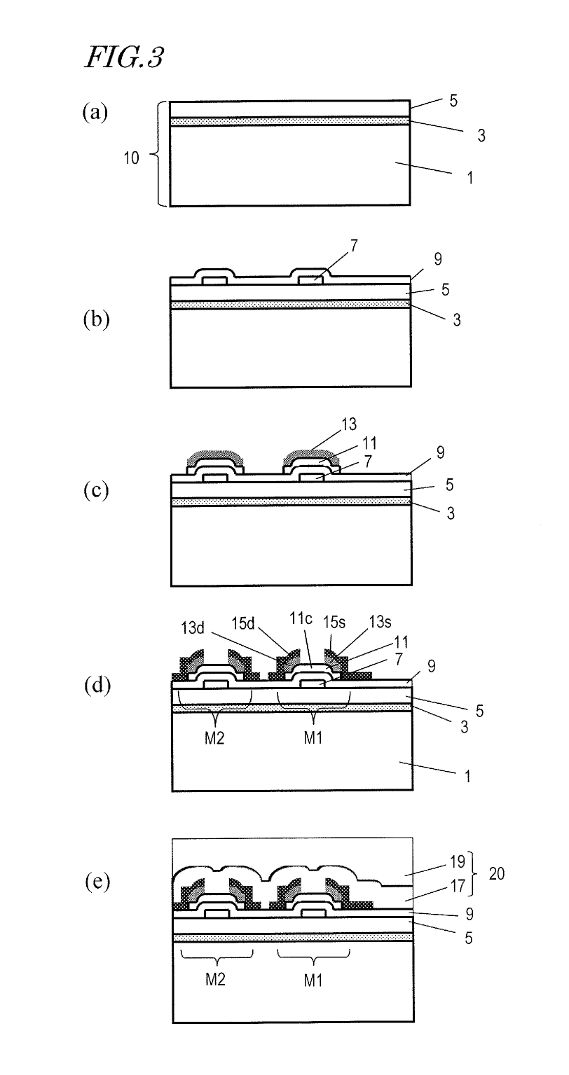

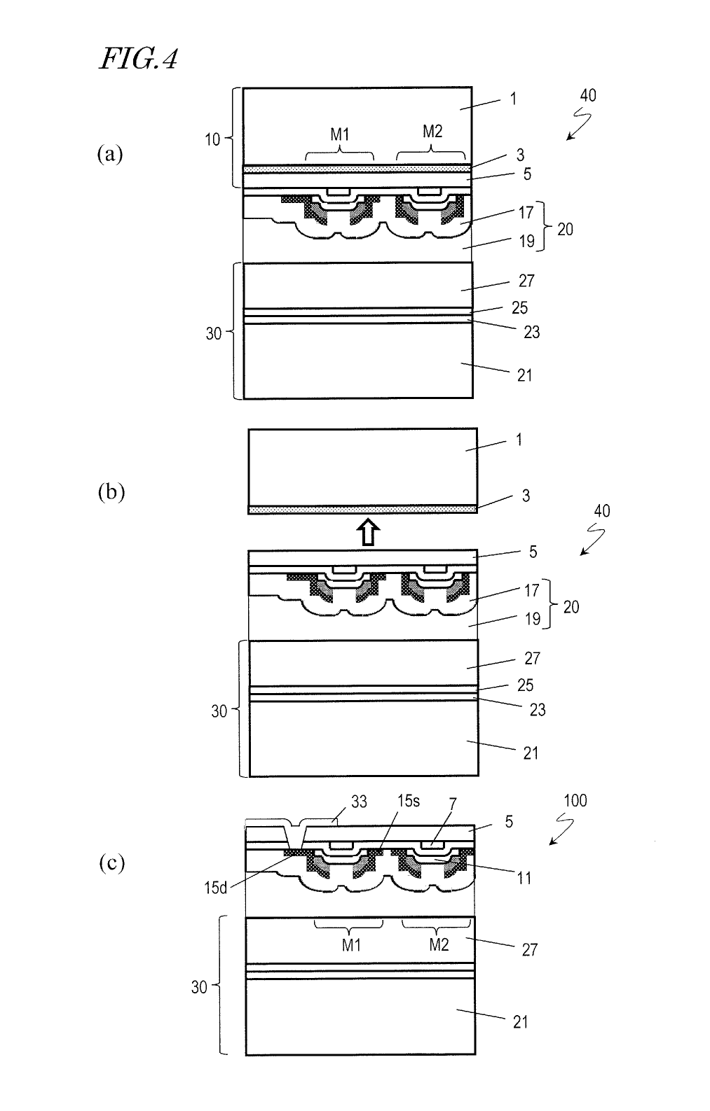

A method for fabricating the TFT substrate of this embodiment will now be described more specifically with reference to FIGS. 3 and 4. In the following description, it will be described how to transfer a plurality of TFTs, including pixel TFTs provided for respective pixels and driver TFTs used in a driver and other circuits, onto a predetermined substrate.

First of all, as shown in FIG. 3(a), a separating layer 3 and a protective layer 5 are stacked in this order on the supporting base 1 such as a glass substrate, thereby obtaining a supporting structure 10.

If the supporting base 1 is to be separated by irradiating the separating layer 3 with a laser beam or any other kind of radiation later in this manufacturing process, a transparent substrate such as a glass substrate is suitably used as the supporting base 1. The transparent substrate suitably has a distortion point which is higher than the process temperature of TFTs. For example, the distortion point is suitably 300° C. or more, and more suitably 600° C. or more. The separating layer 3 suitably includes a material which has a glass transition point or melting point that is higher than the process temperature of the TFTs (which may fall within the range of 300° C. to 600° C., for example) and which absorbs the laser beam or any other radiation. For example, a polyimide resin layer or an amorphous silicon layer may be used as the separating layer 3. For instance, if the polyimide resin layer of the separating layer 3 has a glass transition point of 300° C. to less than 600° C., then the process temperature may be set to fall within the range of 300° C. to less than 600° C. On the other hand, if the separating layer 3 is made of amorphous silicon, the process temperature can be set to be 600° C. or more, which is advantageous. In addition, the supporting base 1 can be peeled off within the layer and/or at the interface of the separating layer 3 by irradiating the separating layer 3 with a laser beam through a laser ablation process in a subsequent process step.

The protective layer 5 just needs to be an insulating layer, but is suitably either an inorganic layer such as a silicon nitride layer or a silicon dioxide layer or a refractory resin layer.

Next, as shown in FIG. 3(b), gate electrodes 7 and a gate insulating layer 9 are formed in this order on the protective layer 5. The gate electrodes 7 are obtained by patterning some metal, for example. It should be noted that the gate electrodes 7 and the gate lines will be made of the same conductive film. The gate insulating layer 9 may be a silicon nitride layer or a silicon dioxide layer, for example.

Subsequently, as shown in FIG. 3(c), a semiconductor layer 11 to be the active layer of the TFTs and a contact layer 13 are stacked in this order on the gate insulating layer 9.

The semiconductor layer 11 is formed by patterning a semiconductor film such as an amorphous silicon film or a crystalline silicon film. If an amorphous silicon layer is formed as the semiconductor layer 11, the contact layer 13 may be an amorphous silicon layer which is heavily doped with a dopant such as phosphorus (P). In the example illustrated in FIG. 3, two semiconductor films to be the semiconductor layer 11 and the contact layer 13 are stacked in this order and then patterned simultaneously into islands of a semiconductor, thereby obtaining the semiconductor layer 11 and the contact layer 13.

It should be noted that if the semiconductor layer 11 and source and drain electrodes to be formed later have sufficiently low contact resistance between them, the contact layer 13 may be omitted. Optionally, a polysilicon layer may be formed as the semiconductor layer 11 by crystallizing an amorphous silicon layer through laser crystallization process. In that case, a portion of the polysilicon layer to be connected to the source and drain electrodes may be turned into a region including a dopant at a high concentration by doping the region, for example. In that case, the drivability of the TFTs can be increased, which is particularly advantageous when the TFTs are used as driver TFTs. Also, although not shown in FIG. 3, after an insulating layer has been deposited over the semiconductor layer 11, contact holes that reach the doped region may be cut through it. Then, gate lines, a semiconductor layer and a source line layer can be formed independently of each other.

Next, as shown in FIG. 3(d), source and drain electrodes 15s, 15d are formed on the contact layer 13. In this example, a conductive film is deposited over the contact layer 13 and then patterned, thereby forming source and drain electrodes 15s, 15d and source lines. In this process step, portions of the contact layer 13 which have been located over the channel regions of the semiconductor layer 11 are also removed at the same time. As a result, the contact layer 13 is split into a source contact layer 13s and a drain contact layer 13d. The source electrode 15s is electrically connected to the semiconductor layer 11 through the source contact layer 13s. Likewise, the drain electrode 15d is electrically connected to the semiconductor layer 11 through the drain contact layer 13d. In this manner, thin-film transistors M1 to be pixel TFTs and thin-film transistors M2 to be driver TFTs are formed on the supporting base 1.

In the example illustrated in FIG. 3, the thin-film transistors M1 and M2 each include the gate electrode 7 which is arranged on the protective layer 5, the gate insulating layer 9 which covers the gate electrode 7 and the protective layer 5, the semiconductor layer (active layer) 11 which has been formed on the gate insulating layer 9, and the source and drain electrodes 15s, 15d which have been formed over the semiconductor layer 11 with the contact layers 13s, 13d interposed between them. A portion of the semiconductor layer 11 which overlaps with the gate electrode 7 with the gate insulating layer 9 interposed between them becomes a channel region 11c. And the contact layers 13s and 13d have been formed on right- and left-hand sides of the channel region 11c.

It should be noted that these thin-film transistors M1 and M2 do not have to be formed by the method described above but may be formed by any other process as well. Optionally, the thin-film transistors M1 and M2 may have mutually different structures, too.

Thereafter, as shown in FIG. 3(e), an insulating layer 20 is deposited over the thin-film transistors M1 and M2. In this example, a surface protective layer 17 and a planarizing resin layer 19 are stacked in this order to form the insulating layer 20.

If the TFT substrate of this embodiment is applied to a transmissive display device, the planarizing resin layer and the surface protective layer 17 are suitably transparent. Also, it is recommended that these layers 17 and 19 have a glass transition point or melting point which is higher than the temperature at which the pixel electrodes will be formed later. The surface protective layer 17 is suitably made of a material that does not transmit water or metal ions easily and may be made of silicon nitride, for example. However, as long as the planarizing resin layer 19 is a layer that does not transmit water or metal ions easily, the surface protective layer 17 may be omitted. The planarizing resin layer 19 is suitably a thermosetting resin layer.

Subsequently, as shown in FIG. 4(a), the supporting structure 10 in which the thin-film transistors M1 and M2 have been formed and a sustaining structure 30 are joined together, thereby obtaining a joined structure 40. In this process step, the supporting structure 10 and the sustaining structure 30 are joined together so that the surface of the insulating layer 20 contacts with the sustaining structure 30, i.e., so that the thin-film transistors M1 and M2 face the sustaining structure 30 with the insulating layer 20 interposed between them.

The sustaining structure 30 just needs to include a substrate 27 that will support the thin-film transistors M1 and M2 when this semiconductor device is completed. In the example illustrated in FIG. 4, the sustaining structure 30 has a structure in which a supporting base 21 and the substrate 27 are stacked one upon the other with the separating layer 23 interposed between them. Optionally, not only the separating layer 23 but also an adhesive resin layer 25 may be further interposed between the supporting base 21 and the substrate 27. In this sustaining structure 30, the separating layer 23 and the adhesive resin layer 25 may be stacked in any order. Optionally, the separating layer 23 and the adhesive resin layer 25 may even be the same layer.

To separate the supporting base 21 from the substrate 27 by irradiating them with a laser beam in a subsequent process step, the supporting base 21 is suitably a transparent substrate. The substrate 27 may be a substrate of which the property is determined according to the intended use of the product, and may be resin substrate, for example.

In this example, the sustaining structure 30 and the supporting structure 10 are joined together so that the substrate 27 of the sustaining structure 30 contacts with the insulating layer 20 (which is the planarizing resin layer 19 in this example). If the planarizing resin layer 19 is a thermosetting resin layer, the planarizing resin layer 19 suitably gets cured completely through this joining process step. Optionally, another planarizing or adhesive resin layer may be formed on the substrate 27 of the sustaining structure 30. In that case, the sustaining structure 30 and the supporting structure 10 may be joined together so that either the additional planarizing resin layer or adhesive resin layer contacts with the insulating layer 20.

Thereafter, as shown in FIG. 4(b), the supporting base 1 is separated and removed from the joined structure 40. In this process step, part or all of the separating layer 3 may also be separated, along with the supporting base 1, from the joined structure 40. In this example, the joined structure 40 is irradiated with a laser beam, for example, through the supporting base 1, thereby separating the supporting base 1 from the separating layer 3 or from the interface between the separating layer 3 and the protective layer 5. In the example illustrated in FIG. 4, the surface of the separated joined structure 40 is only the protective layer 5. However, in some cases, the separating layer 3 may be left either partially or entirely on the protective layer 5. Optionally, after the supporting base 1 has been separated, the separating layer 3 left on the surface of the joined structure 40 may be removed.

Next, as shown in FIG. 4(c), on the surface of the joined structure 40, from which the supporting base 1 has already been separated, a pixel electrode 33 is formed opposite from the sustaining structure 30 (on the surface of the protective layer 5 in the example shown in FIG. 4). If part or all of the separating layer 3 is still left on the surface without being removed, then the pixel electrode 33 may be formed on the surface of the separating layer 3, too. Optionally, although not shown in FIG. 4, after the separating layer 3 has been removed and a planarizing resin layer has been formed, the pixel electrode 33 may be formed thereon. Then, the degree of planarity of the pixel electrode 33 can be further increased.

In this example, after a contact hole that reaches the drain electrode 15d has been cut through the protective layer 5 of the joined structure 40, the pixel electrode 33 is formed to cover the protective layer 5 and to fill the contact hole. The pixel electrode 33 may be formed by depositing a conductive film on the protective layer 5 and inside the contact hole and then patterning the conductive film. In this manner, the TFT substrate 100 is completed. If a transparent conductive film of ITO, for example, is used as the conductive film to form the pixel electrode 33, a TFT substrate 100 applicable to a transmissive display device can be obtained. Also, each of the pixel electrodes 33 may be patterned irrespective of the pattern of each layer under the protective layer 5. That is why as viewed from over the protective layer 5, the pixel electrode 33 may be patterned so as to at least partially overlap with the semiconductor layer 11 or the gate electrode 7 of the thin-film transistor M1 as shown in FIG. 4. In this case, if a display medium layer such as a liquid crystal layer is formed on the TFT substrate 100, at least a part of the pixel electrode 33 can be arranged between the semiconductor layer 11 or the gate electrode 7 and the display medium layer. As a result, the area of the pixel electrode 33 can be further increased irrespective of the structure of the transfer layer. In the example shown in FIG. 4, at least a part of the pixel electrode 33 is located between the semiconductor layer 11, gate electrode 7 and source line and the display medium layer.

The TFT substrate 100 thus obtained includes the supporting base 21 on the other side of the substrate 27 (i.e., opposite from the thin-film transistors M1 and M2 with respect to the substrate 27). However, this supporting base (transparent substrate) 21 is removed at an appropriate time before a final product such as a display device is obtained. The supporting base 21 may be removed at any time. Nevertheless, it is recommended that the supporting base 21 be removed either after an FPC board has been mounted onto the TFT substrate 100 which still has the supporting base 21 or after the TFT substrate 100 and a counter substrate have been bonded together. Then, the mounting or bonding process can be carried out with high alignment accuracy.

According to the method described above, thin-film transistors M1 and M2 are formed on the supporting structure including the supporting base 1, and therefore, can be formed without facing any constraint such as the process temperature or the alignment accuracy, unlike a situation where TFTs are formed directly on the substrate 27 such as a resin substrate. As a result, high-definition, high-performance thin-film transistors M1 and M2 can be formed. In addition, as it is not until the thin-film transistors M1 and M2 on the supporting base 1 have been transferred onto the substrate 27 (sustaining structure) that the pixel electrode 33 is formed, the pixel electrode 33 can be arranged on the protective layer 5 so as to overlap with the thin-film transistors M1 and M2 and lines. Consequently, the area of the pixel electrode 33 can be increased and the aperture ratio can be raised. Furthermore, the pixel electrode 33 is formed on a substantially flat surface from which the supporting base 1 has been separated (e.g., the surface of the protective layer 5 in this example). That is why if a display medium layer such as a liquid crystal layer is provided on the TFT substrate 100, the display medium layer can have a substantially uniform thickness.

Furthermore, according to the method described above, a stack in which the supporting base 21 is arranged under the substrate 27 such as a resin substrate is used as the sustaining structure 30. Thus, the TFT substrate 100 completed is supported by the supporting base 21, and therefore, can be handled easily. On top of that, since the pixel electrode 33 is formed with the supporting base 21 still attached, it is possible to prevent a transferred layer, including the thin-film transistors M1 and M2, from being deformed when the pixel electrode 33 is formed. In this case, conventional equipment which has been used in a conventional process to fabricate a liquid crystal display device can be used, which is advantageous, too. What is more, either an FPC board can be mounted, or a terminal section or driver can be arranged by the COG technique, on the other side of the TFT substrate 100 that still has the supporting base 21 opposite from the supporting base 21 (e.g., on the surface of the protective layer 5 in this example). Consequently, it is possible to prevent the alignment accuracy from decreasing due to the deformation of the transferred layer while these members are mounted.

Furthermore, if a display device such as a liquid crystal display device is fabricated by bonding the TFT substrate 100 and the counter substrate together, the following advantages can also be achieved. According to conventional technologies, if a liquid crystal display device is fabricated using a flexible TFT substrate, it is difficult to align the wiring pattern of the flexible substrate with the opaque pattern of the counter substrate, which is a problem. On the other hand, according to this embodiment, the TFT substrate 100 which is still supported by the supporting base can be bonded to a counter substrate, and then the supporting base 21 can be removed. Consequently, the opaque pattern of the counter substrate can be aligned highly accurately with the wiring pattern of the TFT substrate 100, and therefore, a high-definition display device with a high aperture ratio can be obtained.

It should be noted that the supporting base 21 is adhered to the substrate 27 with the separating layer 23 and the adhesive resin layer 25 and can be separated from the TFT substrate 100 by being irradiated with a laser beam by ablation. And the supporting base 21 separated is recyclable, too.

According to the method described above, such a structure in which the substrate 27 and the supporting base 21 are stacked one upon the other with the separating layer 23 interposed between them is used as the sustaining structure 30. However, the sustaining structure 30 just needs to include the substrate 27 and does not have to have the supporting base 21. Nevertheless, if a flexible substrate is used as the substrate 27, it is recommended that the sustaining structure 30 have the supporting base 21. Alternatively, instead of having the supporting base 21, a resin substrate which is thick enough to ensure sufficient strength may be used as the substrate 27, and then may have its thickness reduced through etching after a pixel electrode has been formed and after the mounting process step has been performed.

Hereinafter, it will be described how a display device may be fabricated using the TFT substrate 100 that has been obtained by the method described above. In the following description, it will be described how to fabricate a liquid crystal display device.

First of all, it will be described with reference to FIG. 5 how to make a counter substrate for the display device.

As shown in FIG. 5(a), a supporting base (e.g., a transparent glass substrate) 51 and a substrate (e.g., a resin substrate) 57 are stacked one upon the other with a separating layer 53 and an adhesive resin layer 55 interposed between them. The separating layer 53 and the adhesive resin layer 55 may be stacked in any order. Optionally, the adhesive resin layer 55 and the separating layer 53 may even be the same layer.

Next, as shown in FIG. 5(b), a protective layer 59 is formed on the substrate 57. The protective layer 59 is suitably made of a material that does not transmit water or metal ions easily and may be made of silicon nitride, for example.

Thereafter, as shown in FIG. 5(c), a counter common electrode 61 is formed on the protective layer 59. Although not shown, before the counter common electrode 61 is formed, a black matrix or color filter may be formed as an opaque layer on the protective layer 59. Optionally, the counter common electrode 61 may also be patterned. The counter common electrode 61 may be made of a transparent conductive film of ITO, for example. In this manner, a counter substrate 50 is obtained.

In the example illustrated in FIG. 5, the counter substrate 50 is formed as a stack of the supporting base 51 and the resin substrate 57. That is why while the black matrix or color filter is formed as an opaque layer or while the counter common electrode 61 is being patterned, the supporting base 51 can prevent the resin substrate 57 from being deformed. As a result, these processes can be carried out with high accuracy. It should be noted that if there is no need to form any black matrix or color filter as an opaque layer or to pattern the counter common electrode 61, then the supporting base 51 does not have to be used and the counter substrate 50 may be obtained just by forming the protective layer 59 and the counter common electrode 61 on the resin substrate 57.

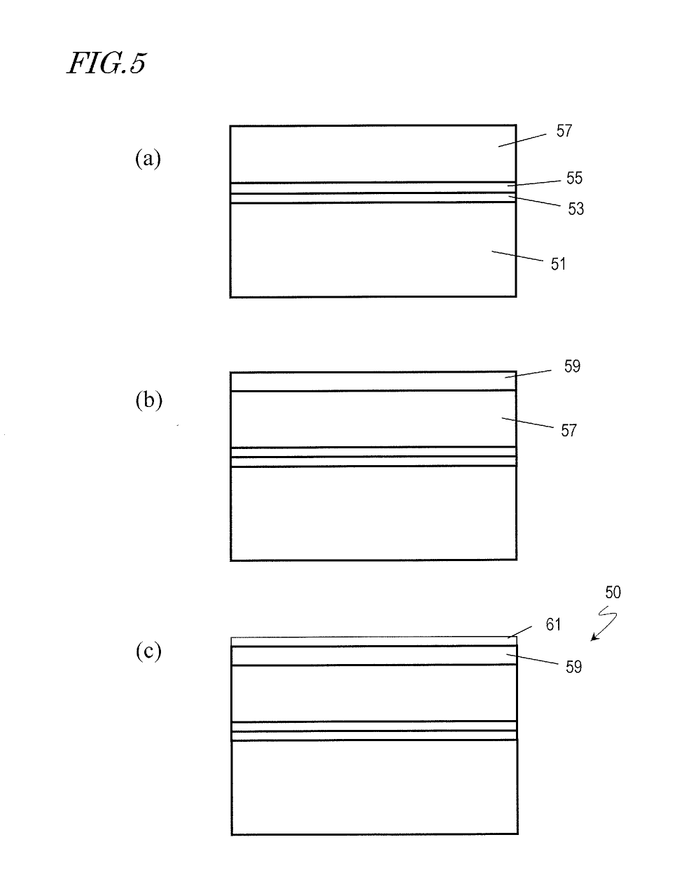

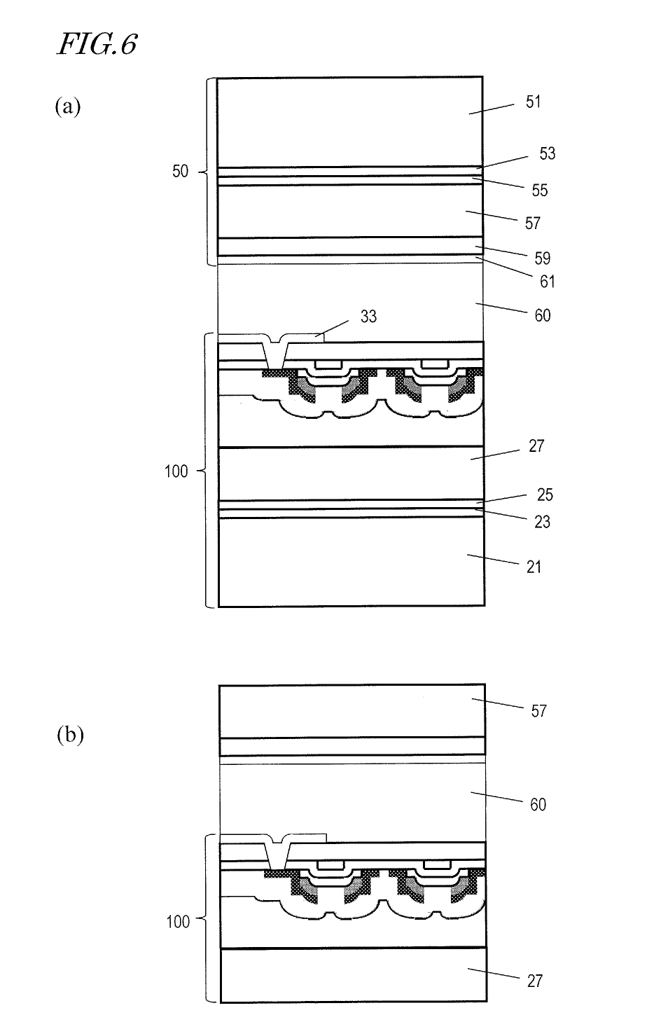

Next, the process step of bonding the counter substrate 50 and the TFT substrate 100 together will be described with reference to FIG. 6.

As shown in FIG. 6(a), the counter substrate 50 and the TFT substrate 100 are arranged so that the pixel electrode faces the counter common electrode 61, and are bonded together so as to interpose a display medium layer 60 between them. In this example, a liquid crystal layer is used as the display medium layer 60. The liquid crystal layer may be formed either before or after those two substrates are bonded together. The thickness of the liquid crystal layer may be controlled with spacers (not shown), for example. The liquid crystal layer and counter substrate 50 do not have to be arranged on a portion of the peripheral area of the TFT substrate 100. After the two substrates have been bonded together, a terminal section or a driver circuit may be arranged in the peripheral area of the TFT substrate 100 by COG method or an FPC board may be mounted thereon.

In this embodiment, the bonding process step and the FPC board mounting process step are performed while the TFT substrate 100 is still supported by the supporting base 21, and therefore, it is possible to prevent the TFT substrate 100 from being deformed due to stress or heat in these process steps. Consequently, the TFT substrate 100 and the counter substrate 50 can be bonded together, and the FPC board can be mounted, highly accurately.

Subsequently, as shown in FIG. 6(b), the supporting base 21 of the TFT substrate 100 is peeled off from either the separating layer 23 or the interface between the separating layer 23 and the adhesive resin layer 25 by being irradiated 23 with a laser beam, for example, through itself. In the same way, the supporting base 51 of the counter substrate 50 is peeled off and removed from the counter substrate 50 by being irradiated with a laser beam, for example, through itself. In this manner, a liquid crystal display device is obtained.

It should be noted that if neither the sustaining structure 30 nor the counter substrate 50 has any supporting bases to peel off during the manufacturing process of the TFT substrate 100, there is no need to perform this peeling process step.

Hereinafter, the configuration of a display device according to this embodiment will be described in further detail.

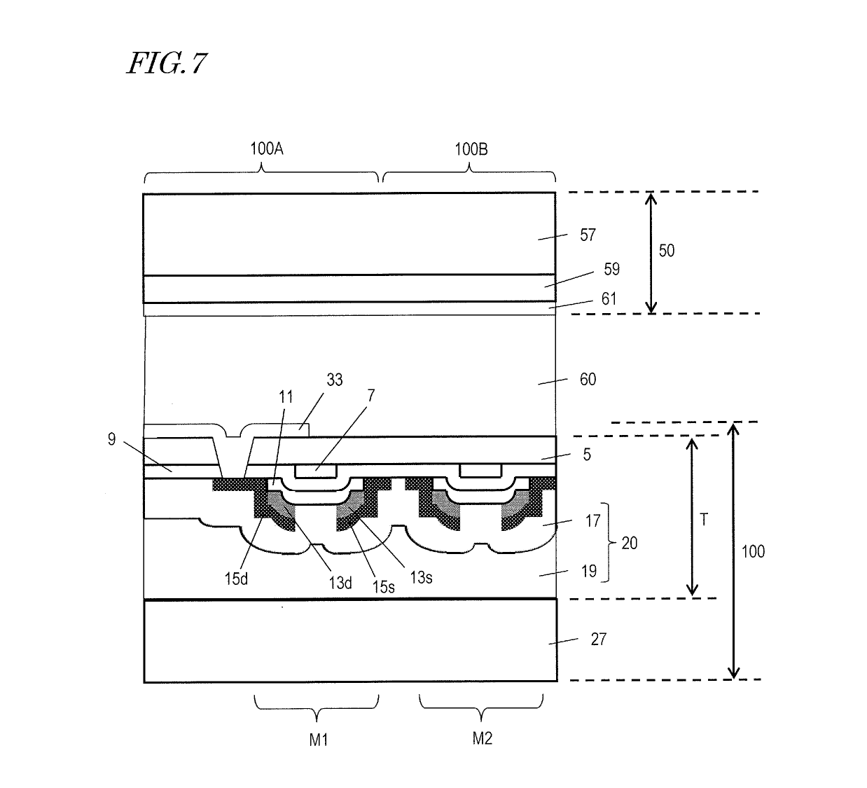

FIG. 7 is a schematic cross-sectional view illustrating a display device according to this embodiment. This liquid crystal display device includes a TFT substrate 100 including thin-film transistors M1 and M2 with a bottom gate structure, a counter substrate 50, and a display medium layer 60 which is interposed between these two substrates. The thin-film transistors M1 and M2 function as a pixel TFT and a driver TFT, respectively. In this example, the display medium layer 60 is a liquid crystal layer.

The TFT substrate 100 includes a substrate (e.g., a resin substrate) 27, a transferred layer T which has been formed on the substrate 27 by transfer process, and a pixel electrode 33 which has been formed on the transferred layer T. The transferred layer T includes a protective layer 5, thin-film transistors M1 and M2 with a bottom gate structure which have been formed on the protective layer 5, and an insulating layer 20 (including a surface protective layer 17 and a planarizing resin layer 19 in this example) which covers these thin-film transistors M1 and M2. And the transferred layer T has been bonded facedown onto the substrate 27. That is to say, look at the configuration of the device on which the transfer process has been performed, and it can be seen that the thin-film transistors M1 and M2 with a bottom gate structure are arranged on the substrate 27 with the insulating layer 20 interposed between them and are covered with the protective layer 5. In other words, if a portion of the thin-film transistors M1 and M2 including the gate electrode 7 is called their lower portion and a portion of the thin-film transistors M1 and M2 including the semiconductor layer 11 is called their upper portion, the TFT substrate 100 and the display medium layer 60 are arranged so that the display medium layer 60 is located under the thin-film transistors M1 and M2.

The pixel electrode 33 has been formed on the surface of the protective layer 5 in contact with the display medium layer 60 and inside a contact hole that has been cut through the protective layer 5. The pixel electrode 33 is electrically connected to the drain electrode 15d of the thin-film transistor M1 inside the contact hole of the protective layer 5. The pixel electrode 33 may be made of a transparent conductive film, for example. The surface of the protective layer 5 in contact with the display medium layer 60 is substantially flat. That is why the pixel electrode 33 can be formed on the flat surface without being affected by the patterns of the underlying layers. Consequently, the thickness of the display medium layer 60 can be made substantially uniform, and an image of high quality can be displayed. In addition, since the pixel electrode 33 can be formed so as to at least partially overlap with the gate electrode 7 and semiconductor layer 11 of the thin-film transistors M1 and M2 (i.e., so as to be located between the gate electrode 7 and semiconductor layer 11 and the display medium layer 60), the area of the pixel electrode 33 can be increased. In the example illustrated in FIG. 7, at least a part of the pixel electrode 33 is arranged between the semiconductor layer 11, gate electrode 7 and source lines and the display medium layer.

On the other hand, the counter substrate 50 includes a resin substrate 57, a protective layer 59 which has been formed on the resin substrate 57, and a counter common electrode 61 which has been formed on the protective layer 59. Although not shown in FIG. 7, a black matrix layer may be provided as an opaque layer between the counter common electrode 61 and the protective layer 59 in order to improve the display quality of the liquid crystal material. Optionally, a color filter may be interposed between the counter common electrode 61 and the protective layer 59. The counter common electrode 61 may also be patterned.

A liquid crystal layer is interposed as the display medium layer 60 between the TFT substrate 100 and the counter substrate 50. Although not shown in FIG. 7, photo spacers may be scattered to keep the thickness of the liquid crystal layer uniform.

Even though TFTs with the bottom gate structure are supposed to be used as the thin-film transistors M1 and M2 in this embodiment, TFTs with a top gate structure may also be used as in an embodiment to be described later. Nevertheless, if such TFTs with the bottom gate structure are used, the contact hole to connect the pixel electrode 33 and the drain electrode 15d together just needs to run through the gate insulating layer 9 and the protective layer 5, and therefore, can have the smaller depth. On top of that, unlike TFTs with the top gate structure, there is no need to cut any contact hole to connect the semiconductor layer and the drain electrode together, which is advantageous, too. On the other hand, if TFTs with the top gate structure are used, the semiconductor layer can turn into polysilicon more easily by being crystallized with a laser beam to realize TFTs with enhanced performance, and the overall size of the device can be reduced because the source and drain regions can be defined by self alignment. The structure of the TFTs may be selected appropriately according to the intended use of the semiconductor device, for example.

FIG. 8 is a plan view illustrating the TFT substrate 100 of the liquid crystal display device shown in FIG. 7.

In the display area 100A of the TFT substrate 100, arranged are source lines S which run in the row direction and gate lines G which run in the column direction. A pixel electrode 33 is arranged in each area (i.e., each pixel) defined by these lines. Also, a thin-film transistor (pixel TFT) M1 is arranged in the vicinity of the intersection between its associated gate line G and source line S.

In the area 100B of the TFT substrate 100 where no pixels have been formed (i.e., in its peripheral area), arranged are a COG chip 94 including a driver (source driver) and an FPC board 90. Each source line S is connected to the source driver via a bonding pad P1 in a terminal section of the TFT substrate 100. Each input terminal of the source driver is connected to its associated external line 92 on the FPC board 90 via a bonding pad P2 in another terminal section of the TFT substrate 100. Although not shown in FIG. 8, another driver (gate driver) is also arranged in this peripheral area 100B. Each gate line G is connected to a gate driver via still another terminal section.

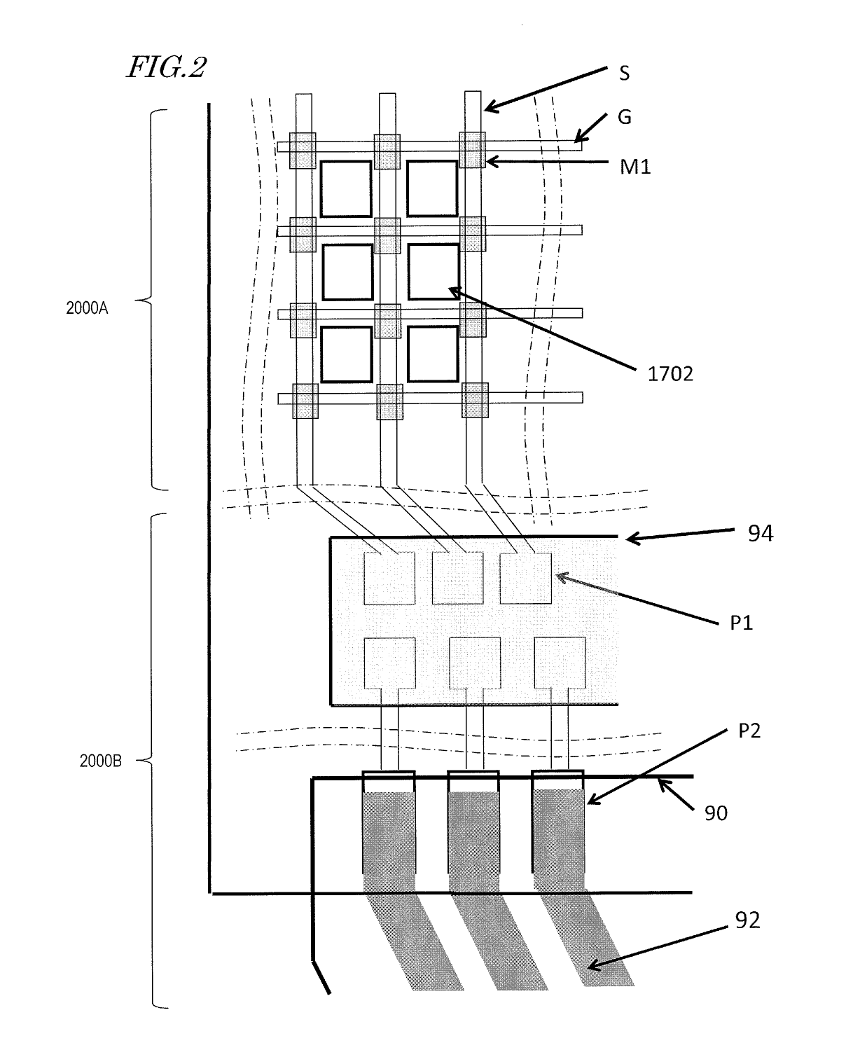

As described above, according to this embodiment, the pixel electrode 33 can be arranged independently of the wiring pattern of the TFT substrate 100 and the arrangement of the thin-film transistor M1. According to the method of Patent Document No. 1 mentioned above, the portion 1702 of the transparent conductive film to be the pixel electrode should be arranged inside each area surrounded with the gate line G and the source line S with some gap left with respect to these lines as shown in FIG. 2. On the other hand, according to this embodiment, the pixel electrode 33 can be arranged so as to partially overlap with the gate lines as can be seen from FIG. 8. Consequently, the aperture ratio can be increased significantly compared to the display device disclosed in Patent Document No. 1.

According to this embodiment, the bonding pads P1 and P2 that form the top surface (i.e., the connecting surface) of the terminal sections can be obtained by patterning the same conductive film as the pixel electrodes 33. In addition, lines which are extended from the display area to the terminal sections can also be made of either a source line layer or a gate line layer. In this description, a layer which is formed by patterning the same conductive film as the source lines S and the source and drain electrodes will be referred to herein as a “source line layer”. The source line layer includes the source lines S and the source and drain electrodes. Likewise, a layer which is formed by patterning the same conductive film as the gate lines G and the gate electrodes will be referred to herein as a “gate line layer”. And a layer which is formed by patterning the same conductive film as the pixel electrodes will be referred to herein as a “pixel electrode layer”.

Hereinafter, the structures of the respective terminal sections that have been defined on the TFT substrate 100 will be described specifically with reference to the accompanying drawings.

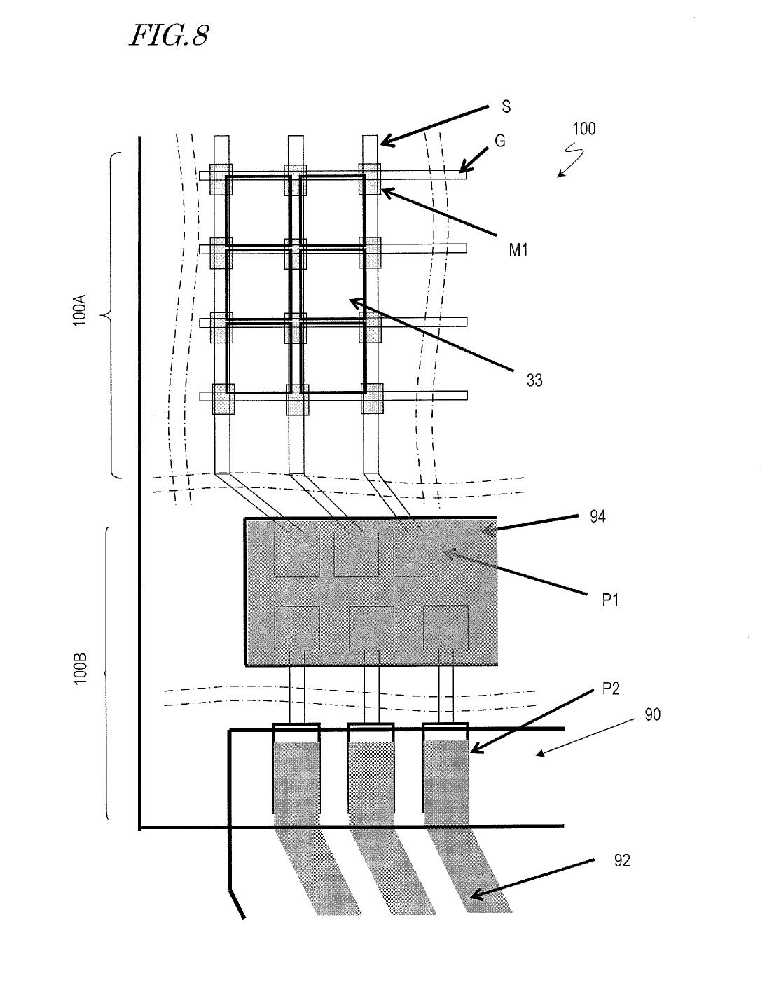

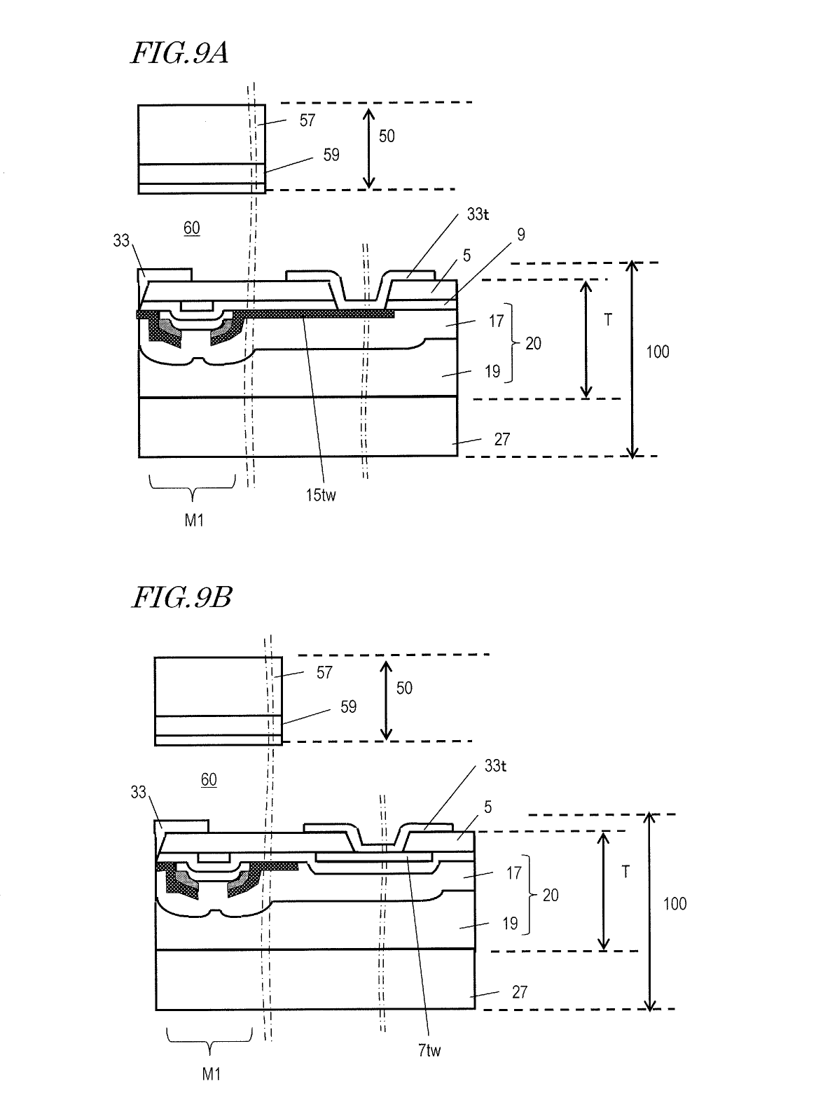

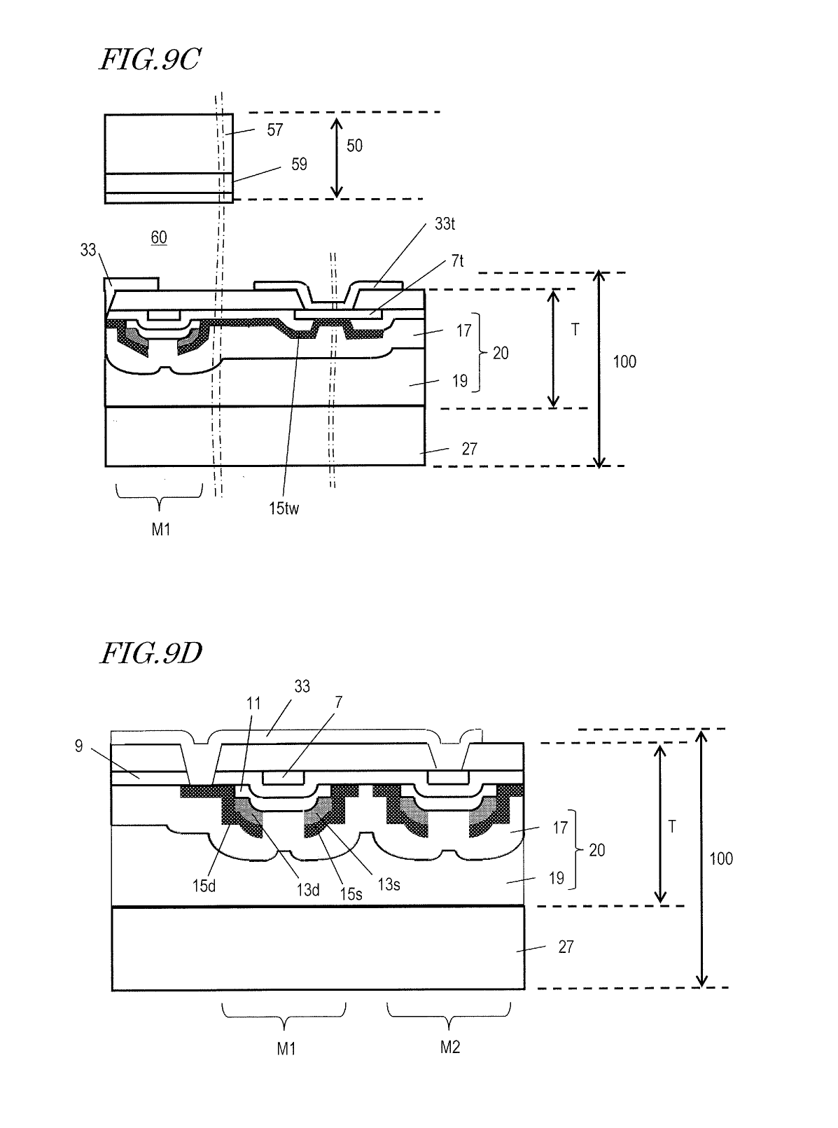

FIG. 9A is a cross-sectional view illustrating a terminal section of the TFT substrate 100. In this structure, a line 15tw which is extended from the display area to the terminal section in the peripheral area has been formed by patterning the same conductive film (i.e., source line layer) as the source and drain electrodes and the source lines S. In the terminal section, a hole that reaches the line 15tw has been cut through the protective layer 5 and the gate insulating layer 9. A conductive layer 33t has been formed inside the hole and on the protective layer 5. The conductive layer 33t is connected to the line 15tw inside the hole. In this embodiment, the conductive layer 33t may be formed simultaneously with the pixel electrodes 33 by patterning the same transparent conductive film as the pixel electrodes 33. This conductive layer 33t may be used as the bonding pads in the plan view shown in FIG. 8.

FIG. 9B is a cross-sectional view illustrating another terminal section of the TFT substrate 100. In this structure, a line 7tw which is extended from the display area to the terminal section in the peripheral area has been formed by patterning the same conductive film (i.e., gate line layer) as the gate lines G. Although not shown in FIG. 9B, the source line S may be connected to the line 7tw. In the terminal section, a hole that reaches the line 7tw has been cut through the protective layer 5 in the peripheral area as shown in FIG. 9B. A conductive layer 33t has been formed inside the hole and on the protective layer 5. The conductive layer 33t is connected to the line 7tw inside the hole. In this embodiment, the conductive layer 33t may also be formed by patterning the same transparent conductive film as the pixel electrodes 33. This conductive layer 33t may also be used as the bonding pads.

Alternatively, a line 15tw which is extended from the display area to the terminal section in the peripheral area may be formed by patterning the source line layer and a conductive layer 7t made of the same conductive film as the gate line G may be arranged between the conductive layer 33t and the line 15tw in the terminal section as shown in FIG. 9C. In that case, the strength of the terminal section can be increased even more effectively. Such a terminal section may be formed in the following manner. First of all, a conductive layer 7t is formed simultaneously with the gate electrodes 7 and the gate lines G by performing the process step that has already been described with reference to FIG. 3(b). Next, a hole is cut through the gate insulating layer 9 and a line 15tw is formed inside the hole by performing the process step that has already been described with reference to FIG. 3(c). The line 15tw can be formed simultaneously with the source and drain electrodes and the source line 2 by patterning the same conductive film. A hole is cut through the protective layer 5 and a conductive layer 33t is formed after the transferring process step has been performed (see FIG. 4(c)).

As can be seen, according to this embodiment, the pixel electrodes 33 are formed after the TFTs have been transferred, and therefore, the conductive layer 33t to form the top layer (i.e., bonding pads) of the terminal section can be formed out of a conductive film with high corrosion resistance to form pixel electrodes. In addition, since a source line layer or gate line layer with low resistance can be extended to the terminal section, the resistance in the terminal section can be decreased to a low level and the power loss can be reduced. On top of that, since the terminal section includes at least the conductive layer 33t and the line 15tw or 7tw of the source or gate line layer, the strength of the terminal section against the pressure to be applied can be increased when the COG chip or FPC board is mounted on the terminal section.

What is more, according to conventional technologies, a contact forming process step to connect pixel electrodes and source lines together and another contact forming process step to connect gate lines and source lines together should be carried out separately. As a result, the manufacturing process gets too complicated and the strength decreases. In contrast, according to this embodiment, in the contact forming process step to be performed after the transferring process step, the semiconductor layer 11 which is connected to the gate line layer and the source line layer (drain electrodes) and the pixel electrode layer can be connected together as shown in FIG. 9D. Consequently, the number of manufacturing process steps to perform can be cut down and the strength can be increased.

### Embodiment 2

Hereinafter, a second embodiment of a semiconductor device according to the present invention will be described. A semiconductor device according to this embodiment is an active-matrix substrate (TFT substrate) including TFTs with a top gate structure.

The TFT substrate of this embodiment is obtained by transferring TFTs with a top gate structure, which have been formed on a supporting base, onto a predetermined substrate such as a resin substrate.

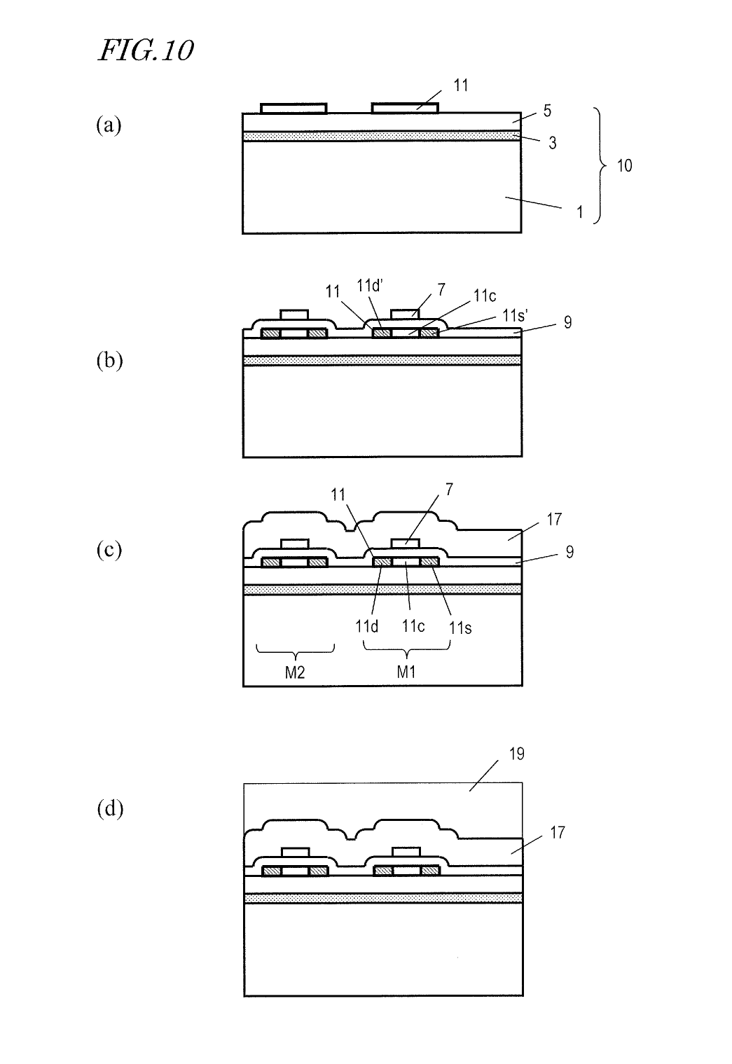

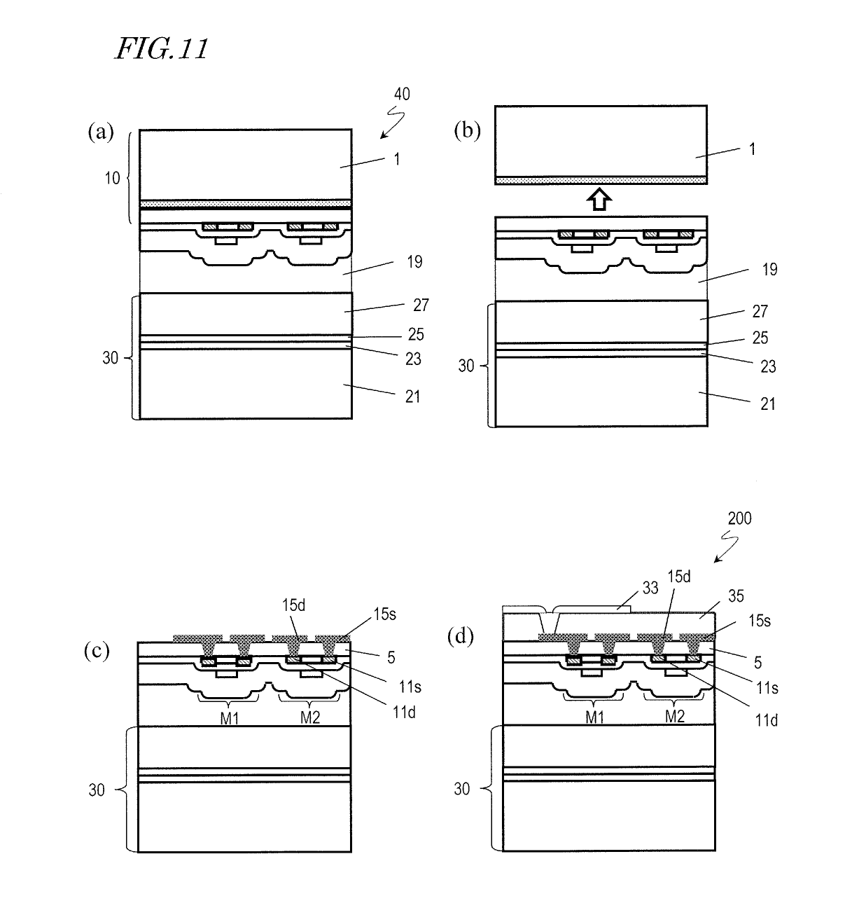

FIGS. 10 and 11 are cross-sectional views illustrating an exemplary series of manufacturing process steps to be performed to fabricate a TFT substrate according to this embodiment. In the following description, it will be described how to transfer a plurality of TFTs, including pixel TFTs provided for respective pixels and driver TFTs used in a driver and other circuits, onto a predetermined substrate. In FIGS. 10 and 11, any component having substantially the same function as its counterpart that has already been described with reference to FIGS. 3 and 4 is identified by the same reference numeral.

First of all, as shown in FIG. 10(a), a separating layer 3 and a protective layer 5 are stacked in this order on the supporting base 1 such as a glass substrate, thereby obtaining a supporting structure 10. The supporting structure 10 may be made of the same materials, and may be formed in the same way, as the supporting structure 10 that has already been described with reference to FIG. 3(a).

Thereafter, a semiconductor layer 11 comprised of islands of semiconductor is formed on the protective layer 5 as an active layer for TFTs. The semiconductor layer 11 may be obtained by patterning an amorphous silicon film or a crystalline silicon film, for example. The semiconductor layer 11 may be formed in the same way as what has already been described with reference to FIG. 3(c).

In this embodiment, a polysilicon layer is formed as the semiconductor layer 11. Specifically, first of all, an amorphous silicon film is deposited on the protective layer 5. Next, a polysilicon film is formed by crystallizing the amorphous silicon film by irradiating it with a laser beam, for example. And then a polysilicon layer is obtained by patterning the polysilicon film.

Subsequently, as shown in FIG. 10(b), a gate insulating layer (which may be made of silicon nitride or silicon dioxide, for example) 9 is formed so as to cover the semiconductor layer 11 and then gate electrodes (made of a metal layer, for example) 7 are formed on the gate insulating layer 9. Next, using the gate electrodes 7 as a mask, dopant ions are implanted into exposed portions of the semiconductor layer 11 which are not covered with the gate electrodes 7. In this manner, heavily doped regions 11s′ and 11d′ to be source and drain regions are defined in the semiconductor layer 11. The portions of the semiconductor layer 11 which are covered with the gate electrodes 7 and to which no dopant ions have been implanted will be channel regions 11c.

Thereafter, as shown in FIG. 10(c), a surface protective layer (which may be made of silicon nitride, for example) 17 is deposited over the gate electrodes 7 and the gate insulating layer 9. The surface protective layer 17 may be made of the same material as the surface protective layer that has already been described with reference to FIG. 3(e). In this state, the dopant ions that have been implanted into the heavily doped regions are activated at a temperature of 500° C. or more (i.e., subjected to an activation annealing process), thereby obtaining source and drain regions 11s and 11d. In this manner, thin-film transistors M2 to be driver TFTs and thin-film transistors M1 to be pixel TFTs are formed on the supporting base 1.

Optionally, these thin-film transistors M1 and M2 may have mutually different structures. In addition, these thin-film transistors M1 and M2 do not have to be made by the method described above but may also be made by any other process. For example, an amorphous silicon film may be formed on the protective layer 5, dopant ions may be implanted into a predetermined region of the amorphous silicon film, and then the amorphous silicon film may be crystallized. In that case, in the process step of crystallizing the amorphous silicon film (with a laser beam, for example), the dopant ions that have been implanted can be activated, and therefore, the activation annealing process step described above can be omitted.

Subsequently, as shown in FIG. 10(d), a planarizing resin layer 19 is formed on the surface protective layer 17. The planarizing resin layer 19 may be made of the same material as the planarizing resin layer 19 that has already been described with reference to FIG. 3(e).

Thereafter, as shown in FIG. 11(a), the supporting structure 10 in which these thin-film transistors M1 and M2 have been formed and the sustaining structure 30 are joined together so that the planarizing resin layer 19 contacts with the sustaining structure 30, thereby obtaining a joined structure 40.

The sustaining structure 30 may have the same structure as what has already been described with reference to FIG. 4(a). In the example shown in FIG. 11, the sustaining structure 30 has a structure in which a supporting base 21 and a substrate 27 are stacked one upon the other with a separating layer 23 interposed between them. The substrate 27 may have its property determined by the intended use of the product and may be a resin substrate, for example.

Next, as shown in FIG. 11(b), the supporting base 1 is separated and removed from the joined structure 40. In this example, the joined structure 40 is irradiated with a laser beam, for example, through the supporting base 1, thereby separating the supporting base 1 from the separating layer 3 or from the interface between the separating layer 3 and the protective layer 5. In the example illustrated in FIG. 11, the surface of the separated joined structure 40 is only the protective layer 5. However, in some cases, the separating layer 3 may be left either partially or entirely on the protective layer 5. Optionally, after the supporting base 1 has been separated, the separating layer left on the surface of the joined structure 40 may be removed.

Subsequently, as shown in FIG. 11(c), contact holes are cut through the protective layer 5 to reach the source and drain regions 11s, 11d, respectively, and then a conductive film is deposited over the protective layer 5 and inside the contact holes. By patterning this conductive film, source and drain electrodes 15s and 15d which are electrically connected to the source and drain regions 11s and 11d, respectively, are formed.

Thereafter, as shown in FIG. 11(d), a planarizing resin layer 35 is formed so as to cover an interconnect layer (source line layer) including the source and drain electrodes 15s and 15d. Next, a contact hole is cut through the planarizing resin layer 35 to reach the drain electrode 15d, and a pixel electrode 33 is formed on the planarizing resin layer 35 and inside the contact hole. The pixel electrode 33 may be formed by depositing a transparent conductive film on the planarizing resin layer 35 and inside the contact hole and then patterning the transparent conductive film. In this manner, a TFT substrate 200 is completed.

The TFT substrate 200 thus obtained includes the supporting base 21 on the back surface of the sustaining structure 30. However, this supporting base (transparent substrate) is removed at an appropriate time before a final product such as a display device is obtained. The supporting base 21 may be removed either after an FPC board has been mounted onto the TFT substrate 200 which still has the supporting base 21 or after the TFT substrate 200 and a counter substrate have been bonded together. Then, the mounting or bonding process can be carried out with high alignment accuracy.

The TFT substrate 200 of this embodiment is also applicable to various kinds of display devices. For example, a display device including the TFT substrate 200 can be fabricated by the same method as what has already been described with reference to FIGS. 5 and 6.

FIG. 12 is a cross-sectional view illustrating a liquid crystal display device which has been fabricated using the TFT substrate 200 of this embodiment. In FIG. 12, any component having substantially the same function as its counterpart which has already been described with reference to FIG. 7 is identified by the same reference numeral.

In this liquid crystal display device, the thin-film transistors M1 and M2 have a top gate structure and the source and drain electrodes 15s and 15d are arranged between the semiconductor layer 11 and the display medium layer, which are major differences from the liquid crystal display device shown in FIG. 7.

The TFT substrate 200 includes a substrate (e.g., a resin substrate) 27, a transferred layer T which has been formed on the substrate 27 by transfer process, and a pixel electrode 33 which has been formed on the transferred layer T. The transferred layer T includes a protective layer 5, thin-film transistors M1 and M2 with a top gate structure which have been formed on the protective layer 5, and an insulating layer 20 (including a surface protective layer 17 and a planarizing resin layer 19 in this example) which covers these thin-film transistors M1 and M2. And the transferred layer T has been bonded facedown onto the substrate 27. That is to say, look at the configuration of the device on which the transfer process has been performed, and it can be seen that the thin-film transistors M1 and M2 with a top gate structure are arranged on the substrate 27 with the insulating layer 20 interposed between them and are covered with the protective layer 5. The thin-film transistors M1 and M2 have been formed facedown with respect to the substrate 27. In other words, if a portion of the thin-film transistors M1 and M2 including the gate electrode 7 is called their upper portion and a portion of the thin-film transistors M1 and M2 including the semiconductor layer 11 is called their lower portion, the TFT substrate 200 and the display medium layer 60 are arranged so that the display medium layer 60 is located under the thin-film transistors M1 and M2.

The source and drain electrodes 15s and 15d and the pixel electrode 33 are arranged between the transferred layer T and the display medium layer 60. The source and drain electrodes 15s and 15d have been formed on the surface of the protective layer 5 in contact with the display medium layer 60 and inside the contact holes that have been cut through the protective layer 5. The source electrodes 15s are electrically connected to the source regions 11s of the thin-film transistors M1 and M2 inside the contact holes, and the drain electrodes 15d are electrically connected to the drain regions 11d inside the contact holes. The source and drain electrodes 15s and 15d and the protective layer 5 are covered with the planarizing resin layer 35.

The pixel electrode 33 has been formed on the planarizing resin layer 35 and inside a contact hole that has been cut through the planarizing resin layer 35. The pixel electrode 33 is electrically connected to the drain electrode 15d of the thin-film transistor M1 inside the contact hole. The pixel electrode 33 may be made of a transparent conductive film, for example. The pixel electrode 33 can be formed on a flat surface without being affected by the patterns of the underlying layers. Consequently, the thickness of the display medium layer 60 can be made substantially uniform, and an image of high quality can be displayed. In addition, since the pixel electrode 33 can be patterned irrespective of the arrangement of the thin-film transistors M1 and M2 and the wiring pattern, the pixel electrode 33 can be formed between the gate electrodes 7 of the thin-film transistors M1 and M2, the semiconductor layer 11 and the display medium layer 60, and therefore, can have an increased area. In the example illustrated in FIG. 12, a part of the pixel electrode 33 is arranged between the gate electrodes 7, semiconductor layer 11, and source line layer of the thin-film transistors M1 and M2 and the display medium layer 60.

The counter substrate 50 and the display medium layer 60 may have the same structures as their counterparts that have already been described with reference to FIG. 7. Also, the TFT substrate 200 of this embodiment has the same planar structure as the TFT substrate 100 shown in FIG. 8, and its illustration and description will be omitted herein.

According to this embodiment, the same effects as the ones achieved by the first embodiment described above are also achieved. Specifically, the thin-film transistors M1 and M2 are formed on the supporting base 1, and therefore, can be formed without facing any constraint such as the process temperature or the alignment accuracy, unlike a situation where TFTs are formed directly on the substrate 27 such as a resin substrate. As a result, high-definition, high-performance thin-film transistors M1 and M2 can be formed. In addition, as it is not until the thin-film transistors M1 and M2 on the supporting base 1 have been transferred onto the substrate 27 (sustaining structure) that the pixel electrode 33 is formed, the pixel electrode 33 can be arranged in contact with the display medium layer 60 so as to overlap with the thin-film transistors M1 and M2 and lines. Consequently, the area of the pixel electrode 33 can be increased and the aperture ratio can be raised. Furthermore, the pixel electrode 33 can be formed on a substantially flat surface. That is why if a display medium layer 60 such as a liquid crystal layer is provided on the TFT substrate 200, the display medium layer 60 can have a substantially uniform thickness.

Furthermore, according to the method described above, a source line layer including the source and drain electrodes 15s and 15d is formed on a substantially flat surface, and therefore, these electrodes can be formed highly accurately and a high-definition semiconductor device is realized even more effectively. On top of that, contact holes for use to form pixel electrodes can have their size decreased, which is beneficial, too. Moreover, when various kinds of drivers are formed on the substrate 27, TFTs to form those drivers can have a reduced size, and therefore, the peripheral area of the display device can have its planar area reduced as well.

In this embodiment, a stack in which a supporting base 21 with higher strength than the substrate 27 such as a resin substrate is arranged under the substrate 27 is suitably used as the sustaining structure 30, too. In that case, when a pixel electrode 33 is formed on the TFT substrate 200 or when an FPC board is mounted, the supporting base 21 can prevent a transferred layer, including the thin-film transistors M1 and M2, from being deformed. Consequently, an FPC board can be mounted, or a terminal section or driver can be arranged by the COG technique, highly accurately on the TFT substrate 200. Furthermore, after the TFT substrate 200 and the counter substrate 50 have been bonded together, the supporting base 21 is suitably removed. As a result, the opaque pattern of the counter substrate 50 and the wiring pattern of the TFT substrate 200 can be aligned with each other highly accurately.

In this embodiment, the bonding pads P1 and P2 which form the top surface (connecting surface) of the terminal section can also be formed by patterning the same conductive film as the pixel electrode's 33.

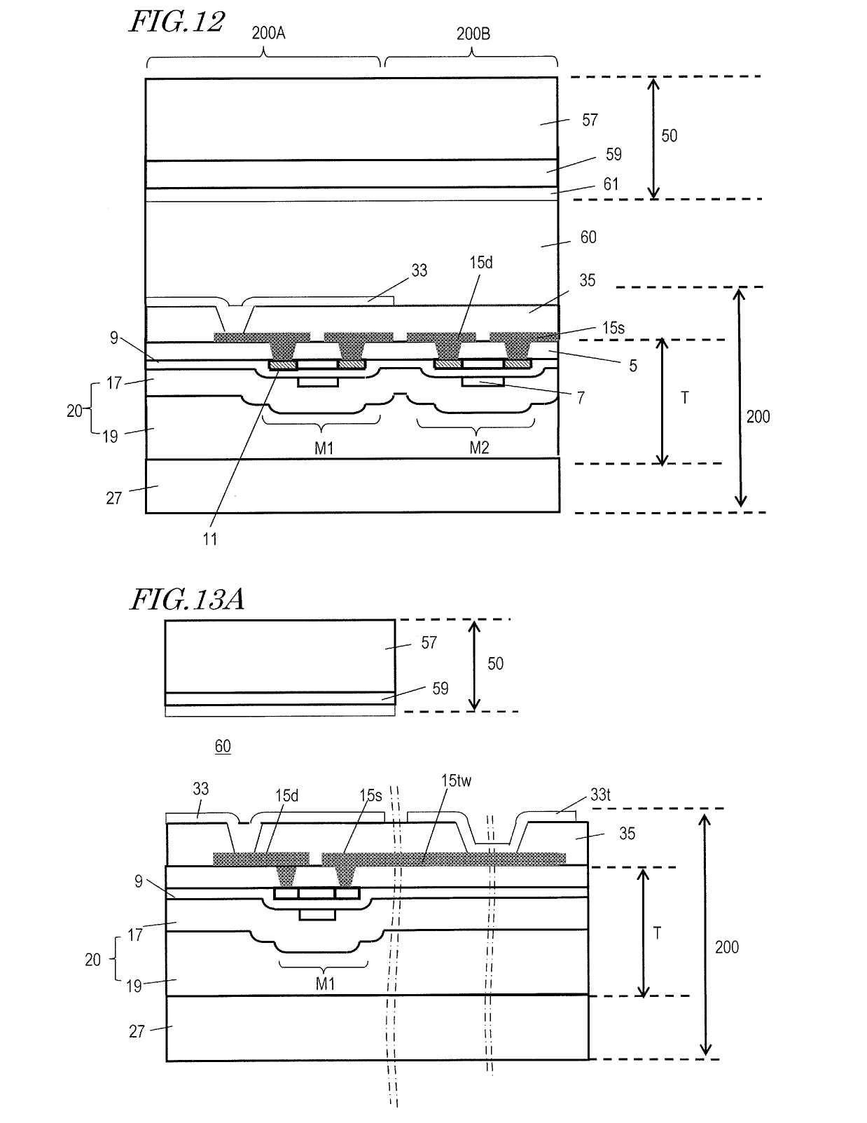

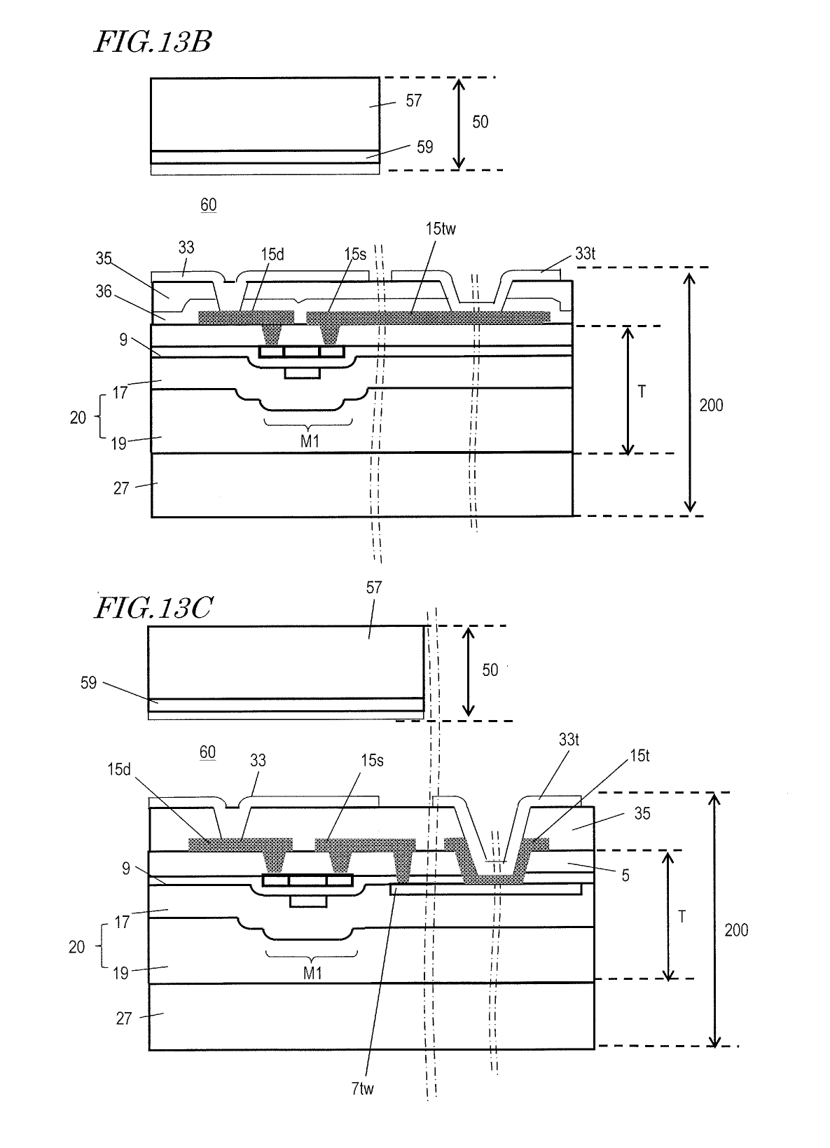

FIGS. 13A through 13C are cross-sectional views illustrating exemplary structures of respective terminal sections which have been formed on the TFT substrate 200.

In the structure shown in FIG. 13A, a line 15tw which has been formed by patterning the same conductive film as the source lines S is extended from the display area to the terminal section of the TFT substrate 200. In the terminal section, a hole that reaches the line 15tw has been cut through the planarizing resin layer 35. A conductive layer 33t has been formed inside the hole and on the planarizing resin layer 35. The conductive layer 33t is connected to the line 15tw inside the hole. In this embodiment, the conductive layer 33t may be formed simultaneously with the pixel electrodes 33 by patterning the same transparent conductive film as the pixel electrodes 33. This conductive layer 33t may be used as bonding pads.

It should be noted that if a terminal section such as the one shown in FIG. 13A is formed, the line 15tw (source line layer), and its portion located in the peripheral area, in particular, might get corroded easily. Thus, to prevent the source line layer from getting corroded, a layer which does not transmit water and metal ions easily is suitably used as the planarizing resin layer 35.

Alternatively, a layer 36 which does not transmit water or metal ions easily (i.e., a protective layer) may also be provided between the source line layer and the planarizing resin layer 35 so as to cover the source line layer as shown in FIG. 13B. Then, it is possible to prevent the source line layer (among other things, the source line 15tw) from getting corroded.

Still alternatively, such a line which is extended from the display area to the terminal section may also be formed by using a gate line layer instead of the source line layer as shown in FIG. 13C.

In the structure shown in FIG. 13C, either the source line S or source electrode is connected to a line 7tw which has been formed by patterning the same conductive film as the gate line's G. The line 7tw is extended from the display area to the terminal section, in which a hole has been cut through the planarizing resin layer 35, protective layer 5 and gate insulating layer 9 to reach the line 7tw. A conductive layer 33t has been formed inside the hole and on the planarizing resin layer 35. The conductive layer 33t may be formed by patterning the same transparent conductive film as the pixel electrode's 33, and is connected to the line 7tw inside the hole via a conductive layer 15t which is made of the same conductive film as the source and drain electrodes. In this manner, the source line S and the conductive layer 33t in the terminal section can be connected together through the line 7tw that has been formed out of the gate line layer.

By adopting the structure shown in FIG. 13C, the line 7tw which is extended from the display area to the peripheral area can be formed inside an area which is covered with the surface protective layer 17 and the protective layer 5, and therefore, it is possible to prevent the line 7tw that forms the terminal section from getting corroded. Consequently, the terminal section obtained can be more reliable than the structure shown in FIG. 13A.

As can be seen, according to this embodiment, the pixel electrodes 33 are formed after the TFTs have been transferred, and therefore, the conductive layer 33t to form the top layer of the terminal section can be formed out of a conductive film with high corrosion resistance to form pixel electrodes 33. In addition, since a source line layer or gate line layer with low resistance can be extended to the terminal section, the resistance in the terminal section can be decreased to a low level and the power loss can be reduced. On top of that, since the terminal section includes at least the conductive layer 33t and the line 15tw or 7tw of the source or gate line layer, the strength of the terminal section against the pressure to be applied can be increased when the COG chip or FPC board is mounted on the terminal section.

According to the method described above, the source and drain electrodes 15s and 15d are supposed to be formed after the supporting structure 10 in which the thin-film transistors M1 and M2 have been formed and the sustaining structure 30 have been joined together. However, the joining process step may also be performed after the source and drain electrodes 15s and 15d have been formed on the supporting structure as in the embodiment described above. Even so, the same effects as the ones described above can also be achieved.

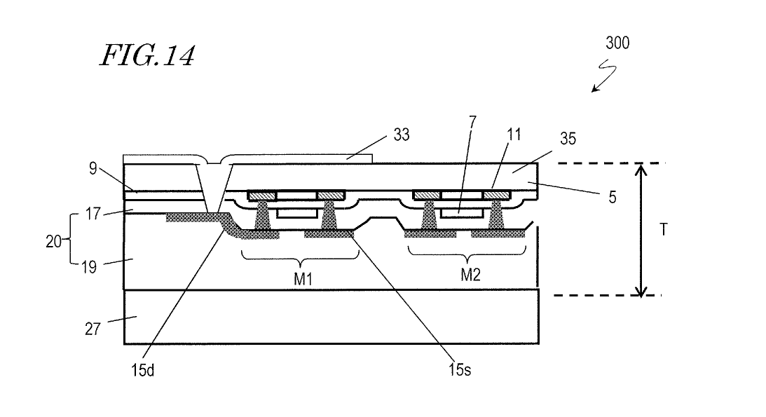

A cross-sectional structure of a TFT substrate 300 which has been obtained by performing the joining process step after the source and drain electrodes 15s and 15d have been formed on the supporting structure is shown in FIG. 14 as an example. In FIG. 14, any component having substantially the same function as its counterpart shown in FIG. 11 is identified by the same reference numeral. In the TFT substrate 300 shown in FIG. 14, there is no need to provide any planarizing resin layer on the protective layer 5, and therefore, the thickness of the display device can be reduced compared to the TFT substrate shown in FIG. 12. In addition, contact holes to form the source and drain electrodes 15s and 15d can be formed with high alignment accuracy.

In the example shown in FIG. 12, the TFTs are supposed to use a polysilicon layer as their semiconductor layer 11. However, TFTs which use an amorphous silicon layer as their semiconductor layer 11 may also be used. In that case, a contact layer may be provided between the semiconductor layer 11 and the source and drain electrodes 15s, 15d. The contact layer may be made of the same material as the contact layer 13 that has already been described with reference to FIG. 7.

In the first and second embodiments described above, the TFT substrate is supposed to be applied to a liquid crystal display device. However, the TFT substrate may also be used in any other kind of display device such as an organic EL display device. Although not shown, an organic EL display device may be obtained by forming an organic layer including an electroluminescent layer on the TFT substrate and then forming an electrode layer thereon. By applying a voltage to between pixel electrodes and a pixel layer, a display operation can be carried out by making the electroluminescent layer emit light on a pixel-by-pixel basis.

As described above, according to embodiments of the present invention, it is not until the thin-film transistors M1 and M2 have been transferred onto the sustaining structure that the pixel electrodes 33 are formed, and therefore, flat pixel electrodes 33, which have been subject to much less process damage or ESD, can be formed. In addition, since the planar area of the pixel electrodes 33 can be increased, the aperture ratio can be raised, too. On top of that, since the alignment accuracy can be increased, a high-definition semiconductor device is realized.

Embodiments of the present invention can be used effectively to fabricate a flexible display. Particularly if a stack of a resin substrate and a supporting base is used as the sustaining structure 30, it is possible to prevent the alignment accuracy from decreasing due to the deformation of the resin substrate in the process step of bonding the TFT substrate 100, 200 or 300 and the counter substrate 50 together. On top of that, since an FPC board to connect a liquid crystal display device to an external circuit can be mounted, or terminals can be arranged by COG method, on the substantially flat surface of the TFT substrate 100, 200 or 300. As a result, the mounting process step can get done with even more stability. Furthermore, the conductive layer 33t can be formed, along with the pixel electrodes 33, on the upper surface of the terminal section by patterning a transparent conductive film to form the pixel electrodes 33, which is advantageous, too.

### INDUSTRIAL APPLICABILITY

Embodiments of the present invention are applicable broadly to any semiconductor device including TFTs such as a TFT substrate and to various kinds of display devices that use such a semiconductor device. If an embodiment of the present invention is applied to a transmissive or reflective flexible display, for example, a high-definition display with a high aperture ratio is realizable. Particularly if an embodiment of the present invention is applied to a transmissive flexible display, the aperture ratio can be increased significantly compared to conventional ones, which is beneficial.

### REFERENCE SIGNS LIST

1 supporting base
3 separating layer
5 protective layer
7 gate electrode
7tw line
7t conductive layer
9 gate insulating layer
10 supporting structure
11 semiconductor layer (TFT's active layer)
11c channel region
11d drain region
11s source region
11s′, lid′ heavily doped region
13 contact layer
13d drain contact layer
13s source contact layer
15d drain electrode
15s source electrode
15t conductive layer
15tw line
17 surface protective layer
19 planarizing resin layer
20 insulating layer
21 supporting base
23 separating layer
25 adhesive resin layer
27 substrate
30 sustaining structure
33 pixel electrode
33t conductive layer
35 planarizing resin layer
36 protective layer
40 joined structure
50 counter substrate
51 supporting base
53 separating layer
55 adhesive resin layer
57 substrate
59 protective layer
60 display medium layer
61 counter common electrode
90 FPC board
92 external line
100, 200, 300 TFT substrate
G gate line
M1 thin-film transistor
M2 thin-film transistor
PI bonding pad
S source line
T transferred layer

1-16. (canceled)

17. A method for fabricating a semiconductor device including a thin-film transistor, the method comprising the steps of:
(A) providing a supporting structure in which a first separating layer and a first insulating layer have been stacked in this order on the surface of a supporting base;
(B) providing a sustaining structure including a substrate;
(C) forming a thin-film transistor, including a semiconductor layer, a gate insulating layer, and a gate electrode, on the first insulating layer;
(D) forming a second insulating layer that covers the thin-film transistor;
(E) joining the supporting structure on which the second insulating layer has been formed onto the sustaining structure so that the thin-film transistor faces the sustaining structure with the second insulating layer interposed, thereby obtaining a joined structure;
(F) removing the supporting base and at least a part of the first separating layer from the joined structure; and
(G) forming a pixel electrode on the other side of the joined structure, from which the supporting base has already been removed, opposite from the sustaining structure so that the pixel electrode is electrically connected to the thin-film transistor, thereby obtaining a TFT substrate,
wherein the method further includes, between the steps (C) and (G), a step (H) of forming source and drain electrodes to be electrically connected to the semiconductor layer; and
wherein, in the step (G), the pixel electrode is formed so as to be in direct contact with the drain electrode of the thin-film transistor.

18. The method of claim 17, wherein the step (H) is performed between the steps (C) and (D); and
wherein the step (D) includes forming the second insulating layer on the source and drain electrodes.

19. The method of claim 18, wherein the thin-film transistor has a bottom gate structure.

20. The method of claim 17, wherein the thin-film transistor has a top gate structure, and
wherein the step (H) is performed between the steps (F) and (G), the step (H) including forming the source and drain electrodes on the other side of the joined structure, from which the supporting base has already been removed, opposite from the sustaining structure so that the source and drain electrodes are electrically connected to the semiconductor layer.

21. The method of claim 20, wherein the step (H) includes forming the source and drain electrodes by cutting a contact hole through the first insulating layer so that the contact hole reaches a portion of the drain electrode and by depositing a conductive layer on the first insulating layer and inside the contact hole.

22. The method of claim 17, wherein the sustaining structure includes a transparent substrate that has been stacked over the substrate with a second separating layer interposed, and
the method further includes, after the step (G) has been performed, the step (I) of removing the transparent substrate and at least a part of the second separating layer from the joined structure.

23. The method of claim 22, further comprising, after the step (G) has been performed, the step (J) of arranging a display medium layer over the pixel electrode of the TFT substrate, and
the step (I) is performed after the step (J).

24. The method of claim 17, wherein the substrate is a resin substrate.

25. The method of claim 24, wherein the resin substrate is transparent.

26. The method of claim 17, further comprising, after the step (G) has been performed, the step (J) of arranging a display medium layer over the pixel electrode of the TFT substrate, and
at least a portion of the pixel electrode is located between the semiconductor layer and the display medium layer.

27. The method of claim 26, wherein the display medium layer is a liquid crystal layer,
the step (I) includes arranging the TFT substrate and a counter substrate, including a counter electrode that has been formed on its surface, with the liquid crystal layer interposed between the two substrates, and
the counter substrate is a resin substrate.

28. A semiconductor device comprising:
a TFT substrate including a thin-film transistor with a bottom gate structure;
a display medium layer which is arranged on the TFT substrate;
a transparent pixel electrode which is electrically connected to a drain electrode of the thin-film transistor; and
an insulating layer which is formed between the drain electrode and the pixel electrode,
wherein the insulating layer has an opening;
a part of the pixel electrode is formed in the opening so as to be in direct contact with the drain electrode in the opening; and
if a portion of the thin-film transistor including the gate electrode is called its lower portion and a portion of the thin-film transistor including the semiconductor layer is called its upper portion, the TFT substrate and the display medium layer are arranged so that the display medium layer is located under the thin-film transistor, and
at least a portion of the pixel electrode is located between the gate electrode of the thin-film transistor and the display medium layer.

29. The semiconductor device of claim 28, further comprising a line which is formed out of the same conductive film as the pixel electrode, the line connecting a first conductive layer which is formed out of the same conductive film as the drain electrode and a second conductive layer which is formed out of the same conductive film as a gate electrodes of the thin-film transistor together.

30. A semiconductor device comprising:
a TFT substrate including a thin-film transistor with a top gate structure;
a display medium layer which is arranged on the TFT substrate; and
a transparent pixel electrode which is electrically connected to the thin-film transistor,
wherein source and drain electrodes of the thin-film transistor are formed between a semiconductor layer of the thin-film transistor and the pixel electrode, the pixel electrode being in direct contact with the drain electrode; and
if a portion of the thin-film transistor including the gate electrode is called its upper portion and a portion of the thin-film transistor including the semiconductor layer is called its lower portion, the TFT substrate and the display medium layer are arranged so that the display medium layer is located under the thin-film transistor, and
at least a portion of the pixel electrode is located between the semiconductor layer of the thin-film transistor and the display medium layer.

31. The semiconductor device of claim 28, wherein the display medium layer is a liquid crystal layer,
the device further includes a counter substrate which is arranged to face the TFT substrate with the liquid crystal layer interposed, and
the counter substrate and the TFT substrate each include a transparent resin substrate.

32. The semiconductor device of claim 30, further comprising an insulating layer which is formed between the drain electrode and the pixel electrode,
wherein the insulating layer has an opening; and
a part of the pixel electrode is formed in the opening so as to be in direct contact with the drain electrode in the opening.
